(19) United States
(12) Patent Application Publication
(10) Pub. No.: US 2026/0198288 A1
(43) Pub. Date: Jul. 9, 2026

(54) SEMICONDUCTOR DEVICE

(71) Applicant: Taiwan Semiconductor Manufacturing Company, Ltd., Hsinchu (TW)

(72) Inventor: Jhon-Jhy LIAW, Zhudong Township (TW)

(73) Assignee: Taiwan Semiconductor Manufacturing Company, Ltd., Hsinchu (TW)

(21) Appl. No.: 19/012,359

(22) Filed: Jan. 7, 2025

(51) Int. Cl. H01L 23/528; H10B 10/00; H10D 84/83

(52) U.S. Cl. CPC H10W 20/427; H10B 10/125; H10D 84/832

(57) ABSTRACT

A semiconductor device includes a transistor cell having a first pass-gate transistor, a second pass-gate transistor, a first pull-down transistor, and a second pull-down transistor, and a bit-line conductor, a bit-line-bar conductor, a first VSS conductor, and a second VSS conductor extending in a first direction. The bit-line conductor and the bit-line-bar conductor are respectively under and electrically connected to source/drain features of the first pass-gate transistor and the second pass-gate transistor. The first VSS conductor and the second VSS conductor are respectively over and electrically connected to source/drain features of the first pull-down transistor and the second pull-down transistor. A width of the first VSS conductor and the second VSS conductor in a second direction is greater than a width of the bit-line conductor and the bit-line-bar conductor in the second direction. The second direction is perpendicular to the first direction.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) transistors have been incorporated into memory devices (including, for example, static random-access memory, or SRAM, cells) to reduce chip footprint while maintaining reasonable processing margins.

However, as GAA transistors and transistor cells continue to be scaled down, interconnection routing for memory array uses too many routing resources and therefore impact the cell scaling as well as cell performance. Accordingly, although existing technologies for fabricating memory array including GAA transistors have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIG. 2 illustrates a fragmentary diagrammatic top view of an array of SRAM cells that can be implemented in a memory region of the IC chip in FIG. 1, in accordance with some embodiments of the present disclosure.

FIGS. 3 and 4 illustrates circuit diagrams of an SRAM circuit that can be implemented in an SRAM cell of an array in the memory region of the IC chip in FIG. 1, in accordance with some embodiments of the present disclosure.

FIG. 5 illustrates a perspective view of a GAA transistor in an SRAM cell in accordance with some embodiments of the present disclosure.

FIG. 6 illustrates a cross sectional view of a semiconductor device for illustrating a front-side interconnection and a back-side interconnection, in accordance with some embodiments of the present disclosure.

FIGS. 7A and 7B illustrate top views (or layouts) of an SRAM cell in a semiconductor device, in accordance with some embodiments of the present disclosure, in which FIG. 7A illustrates the features in a device region and a front-side interconnection structure, and FIG. 7B illustrates the features in the device region and a back-side interconnection structure.

FIG. 7C illustrates an X-Z cross-sectional view of the SRAM cell in the semiconductor device along a line C-C′ in FIGS. 7A and 7B, in accordance with some embodiments of the present disclosure.

FIG. 7D illustrates an X-Z cross-sectional view of the SRAM cell in the semiconductor device along a line D-D′ in FIGS. 7A and 7B, in accordance with some embodiments of the present disclosure.

FIG. 7E illustrates an X-Z cross-sectional view of the SRAM cell in the semiconductor device along a line E-E′ in FIGS. 7A and 7B, in accordance with some embodiments of the present disclosure.

FIG. 7F illustrates a Y-Z cross-sectional view of the SRAM cell in the semiconductor device along a line F-F′ in FIGS. 7A and 7B, in accordance with some embodiments of the present disclosure.

FIG. 7G illustrates a Y-Z cross-sectional view of the SRAM cell in the semiconductor device along a line G-G′ in FIGS. 7A and 7B, in accordance with some embodiments of the present disclosure.

FIG. 7H illustrates a Y-Z cross-sectional view of the SRAM cell in the semiconductor device along a line H-H′ in FIGS. 7A and 7B, in accordance with some embodiments of the present disclosure.

FIG. 8 illustrates a cross sectional view of tap structures in FIG. 2 for connecting the metal conductor at the back-side to a front-side metal conductor at the front-side, in accordance with some embodiments of the present disclosure.

FIGS. 9A and 9B illustrate top views (or layouts) of an SRAM cell in a semiconductor device, in accordance with some alternative embodiments of the present disclosure, in which FIG. 9A illustrates the features in a device region and a front-side interconnection structure, and FIG. 9B illustrates the features in the device region and a back-side interconnection structure.

FIG. 9C illustrates an X-Z cross-sectional view of the SRAM cell in the semiconductor device along a line C-C′ in FIGS. 9A and 9B, in accordance with some alternative embodiments of the present disclosure.

FIG. 9D illustrates a Y-Z cross-sectional view of the SRAM cell in the semiconductor device along a line F-F′ in FIGS. 9A and 9B, in accordance with some alternative embodiments of the present disclosure.

FIGS. 10A and 10B illustrate top views (or layouts) of an SRAM cell in a semiconductor device, in accordance with some alternative embodiments of the present disclosure, in which FIG. 10A illustrates the features in a device region and a front-side interconnection structure, and FIG. 10B illustrates the features in the device region and a back-side interconnection structure.

FIG. 10C illustrates an X-Z cross-sectional view of the SRAM cell in the semiconductor device along a line E-E′ in FIGS. 10A and 10B, in accordance with some alternative embodiments of the present disclosure.

FIG. 10D illustrates a Y-Z cross-sectional view of the SRAM cell in the semiconductor device along a line F-F′ in FIGS. 10A and 10B, in accordance with some alternative embodiments of the present disclosure.

FIGS. 11A and 11B illustrate top views (or layouts) of an SRAM cell in a semiconductor device, in accordance with some alternative embodiments of the present disclosure, in which FIG. 11A illustrates the features in a device region and a front-side interconnection structure, and FIG. 11B illustrates the features in the device region and a back-side interconnection structure.

FIG. 11C illustrates an X-Z cross-sectional view of the SRAM cell in the semiconductor device along a line C-C′ in FIGS. 11A and 11B, in accordance with some alternative embodiments of the present disclosure.

FIG. 11D illustrates an X-Z cross-sectional view of the SRAM cell in the semiconductor device along a line D-D′ in FIGS. 11A and 11B, in accordance with some alternative embodiments of the present disclosure.

FIG. 11E illustrates an X-Z cross-sectional view of the SRAM cell in the semiconductor device along a line E-E′ in FIGS. 11A and 11B, in accordance with some alternative embodiments of the present disclosure.

FIG. 11F illustrates a Y-Z cross-sectional view of the SRAM cell in the semiconductor device along a line G-G′ in FIGS. 11A and 11B, in accordance with some alternative embodiments of the present disclosure.

FIGS. 12A and 12B illustrate top views (or layouts) of an SRAM cell in a semiconductor device, in accordance with some alternative embodiments of the present disclosure, in which FIG. 12A illustrates the features in a device region and a front-side interconnection structure, and FIG. 12B illustrates the features in the device region and a back-side interconnection structure.

FIGS. 13A and 13B illustrate top views (or layouts) of an SRAM cell in a semiconductor device, in accordance with some alternative embodiments of the present disclosure, in which FIG. 13A illustrates the features in a device region and a front-side interconnection structure, and FIG. 13B illustrates the features in the device region and a back-side interconnection structure.

FIG. 13C illustrates an X-Z cross-sectional view of the SRAM cell in the semiconductor device along a line C-C′ in FIGS. 13A and 13B, in accordance with some alternative embodiments of the present disclosure.

FIG. 13D illustrates an X-Z cross-sectional view of the SRAM cell in the semiconductor device along a line D-D′ in FIGS. 13A and 13B, in accordance with some alternative embodiments of the present disclosure.

FIG. 13E illustrates an X-Z cross-sectional view of the SRAM cell in the semiconductor device along a line E-E′ in FIGS. 13A and 13B, in accordance with some alternative embodiments of the present disclosure.

FIG. 13F illustrates a Y-Z cross-sectional view of the SRAM cell in the semiconductor device along a line H-H′ in FIGS. 13A and 13B, in accordance with some alternative embodiments of the present disclosure.

FIGS. 14A and 14B illustrate top views (or layouts) of an SRAM cell in a semiconductor device, in accordance with some alternative embodiments of the present disclosure, in which FIG. 14A illustrates the features in a device region and a front-side interconnection structure, and FIG. 14B illustrates the features in the device region and a back-side interconnection structure.

FIG. 14C illustrates an X-Z cross-sectional view of the SRAM cell in the semiconductor device along a line C-C′ in FIGS. 14A and 14B, in accordance with some alternative embodiments of the present disclosure.

FIG. 14D illustrates an X-Z cross-sectional view of the SRAM cell in the semiconductor device along a line D-D′ in FIGS. 14A and 14B, in accordance with some alternative embodiments of the present disclosure.

FIG. 14E illustrates an X-Z cross-sectional view of the SRAM cell in the semiconductor device along a line E-E′ in FIGS. 14A and 14B, in accordance with some alternative embodiments of the present disclosure.

FIG. 14F illustrates a Y-Z cross-sectional view of the SRAM cell in the semiconductor device along a line H-H′ in FIGS. 14A and 14B, in accordance with some alternative embodiments of the present disclosure.

FIGS. 15A and 15B illustrate top views (or layouts) of an SRAM cell in a semiconductor device, in accordance with some alternative embodiments of the present disclosure, in which FIG. 15A illustrates the features in a device region and a front-side interconnection structure, and FIG. 15B illustrates the features in the device region and a back-side interconnection structure.

FIG. 15C illustrates an X-Z cross-sectional view of the SRAM cell in the semiconductor device along a line C-C′ in FIGS. 15A and 15B, in accordance with some alternative embodiments of the present disclosure.

FIG. 15D illustrates an X-Z cross-sectional view of the SRAM cell in the semiconductor device along a line D-D′ in FIGS. 15A and 15B, in accordance with some alternative embodiments of the present disclosure.

FIG. 15E illustrates an X-Z cross-sectional view of the SRAM cell in the semiconductor device along a line E-E′ in FIGS. 15A and 15B, in accordance with some alternative embodiments of the present disclosure.

FIG. 15F illustrates a Y-Z cross-sectional view of the SRAM cell in the semiconductor device along a line H-H′ in FIGS. 15A and 15B, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to static random-access memory (SRAM) cells having field-effect transistors (FETs), such as three-dimensional gate-all-around (GAA) transistors, in an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include an array of SRAM cells with bit-line conductors and bit-line-bar conductors under the SRAM cells (more specifically, transistors) and VSS conductors over the SRAM cells (more specifically, transistors) with wider widths and thinner thicknesses than the bit-line conductors and the bit-line-bar conductors, such that improve cell performance and reduce routing complexity for SRAM cells. The details of the present disclosure are described below in conjunction with the accompanying drawings, which illustrate the layout and structure of transistor cells, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

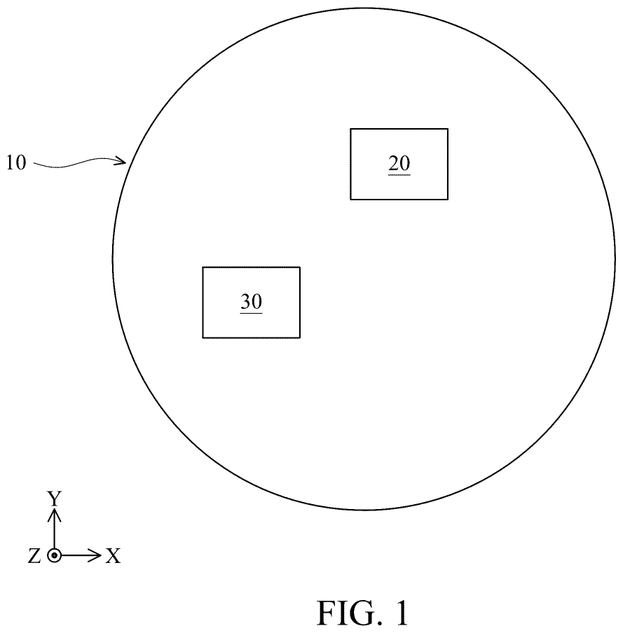

FIG. 1 is a fragmentary diagrammatic top view of an integrated circuit (IC) chip 10, in portion or entirety, in accordance with some embodiments of the present disclosure. IC chip 10 may include various passive microelectronic devices and active microelectronic devices, such as resistors, capacitors, inductors, diodes, p-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or combinations thereof. The various microelectronic devices can be configured to provide IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, IC chip 10 includes a memory region 20 and a logic region 30. Memory region 20 can include an array of memory cells, each of which includes transistors and interconnection structures (also referred to as routing structures) that combine to provide a storage device and/or a storage function, such as a flip flop, a latch, other suitable memory devices, or combinations thereof. In some embodiments, memory region 20 is configured with static random-access memory (SRAM) cells, dynamic random-access memory (DRAM) cells, non-volatile random-access memory (NVRAM) cells, flash memory cells, other suitable memory cells, or combinations thereof. Logic region 30 can include an array of standard cells, each of which includes transistors and interconnection structures that combine to provide a logic device and/or a logic function, such as an inverter, an AND gate, an NAND gate, an OR gate, an NOR gate, a NOT gate, an XOR gate, an XNOR gate, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of IC chip 10.

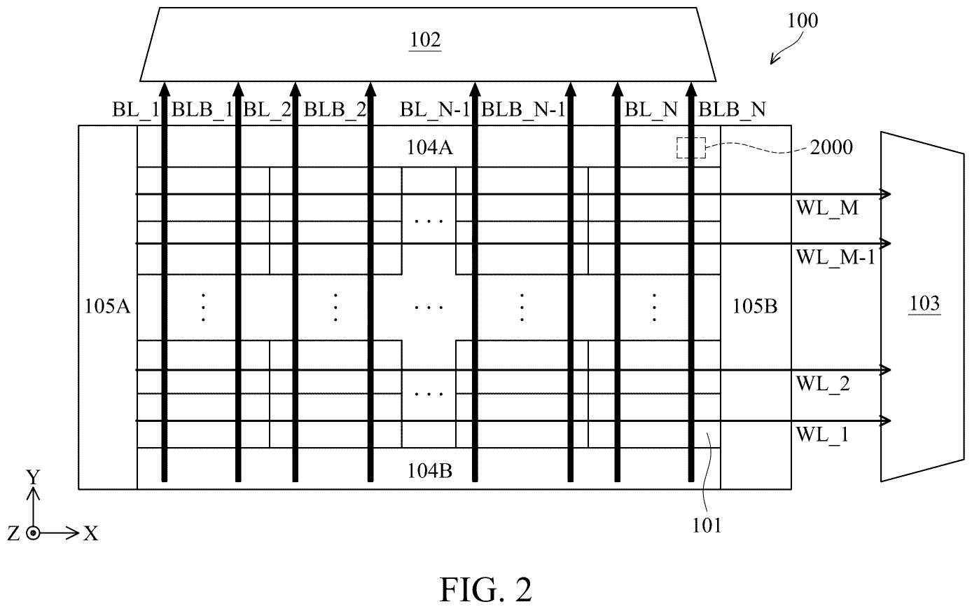

FIG. 2 is a fragmentary diagrammatic top view of an array 100 of SRAM cells 101 that can be implemented in the memory region 20 of FIG. 1, in accordance with some alternative embodiments of the present disclosure. FIG. 2 has been simplified for the sake of clarity to better understand the inventive concepts of the present disclosure. Additional features can be added in the array 100, and some of the features described below can be replaced, modified, or eliminated in other embodiments of the array 100.

The array 100 includes SRAM cells 101 arranged with pluralities of columns and rows. Each of columns of the SRAM cells 101 includes a bit line pair extending in a Y-direction, such as a bit-line conductor (BL_1, BL_2, . . . , BL_N-1, BL_N) and a bit-line-bar conductor (also referred to as a complementary bit line) (BLB_1, BLB_2, . . . , BLB_N-1, BLB_N), that facilitate reading data from and/or writing data to respective SRAM cells 101 in true form and complementary form on a column-by-column basis. Each of rows of the SRAM cells 101 includes a word-line conductor (WL_1, WL_2, . . . , WL_M-1, WL_M) extending in the X-direction perpendicular to the Y-direction, that facilitates access to respective SRAM cells 101 on a row-by-row basis. Each of SRAM cells 101 is electrically connected to a respective bit-line conductor, a respective bit-line-bar conductor, and a respective word-line conductor, in which the bit-line conductors and the bit-line-bar conductors are electrically connected to a controller 102 and the word-line conductors are electrically connected to a controller 103.

The controllers 102 and 103 include any circuitry suitable to facilitate read/write operations from/to the SRAM cells 101, including but not limited to, a column decoder circuit, a row decoder circuit, a column selection circuit, a row selection circuit, a read/write circuit (for example, configured to read data from and/or write data to the SRAM cells 101 corresponding to a selected bit line pair (in other words, a selected column)), other suitable circuit, or combinations thereof. In some implementations, the controllers 102 and 103 includes at least one sense amplifier configured to detect and/or amplify a voltage differential of a selected bit line pair. In some implementations, the sense amplifier is configured to latch or otherwise store data values of the voltage differential.

The array 100 further includes edge cell regions 105A and 105B on edges of the array 100 in the Y-direction. The edge cell regions 105A and 105B include dummy cells for ensuring uniformity in performance of SRAM cells 101. Dummy cells are configured physically and/or structurally similar to SRAM cells 106, but do not store data. For example, dummy cells may include p-type wells, n-type wells, nanostructures, gate structures, source/drain features, and/or contact features.

The array 100 also includes edge strap regions 104A and 104B on edges of the array 100 in the X-direction. The edge strap regions 104A and 104B does not contain SRAM cells and is used for implementing well pick-up structures or well strap cells configured to electrically couple a voltage to an n-well or a p-well of the SRAM cells 101.

In the present disclosure, some conductors for interconnection of the array 100 of the SRAM cells 101 are disposed under the SRAM cells 101 (on back-side of the SRAM cells 101). For example, the bit-line conductors (BL_1, BL_2, . . . , BL_N-1, BL_N) and the bit-line-bar conductors (BLB_1, BLB_2, . . . , BLB_N-1, BLB_N) shown in FIG. 2 are disposed under and electrically connected to the SRAM cells 101, will discussed in below. In order to electrically connect the bit-line conductors and the bit-line-bar conductors to the controller 102, the bit-line conductors and the bit-line-bar conductors under the SRAM cells 101 are routed to front-side conductors over the SRAM cells 101 through tap structures (e.g., tap structures 2000) located in the edge strap regions 104A or 104B, and then the front-side conductors are electrically connected to the controller 102. In some embodiments, the conductors for word-lines, VDD lines, or VSS lines disposed under the SRAM cells 101 may also be routed to the front-side conductors over the SRAM cells 101 through the tap structures located in the edge strap regions 104A/104B and the edge cell regions 105A/105B. The details of the tap structures are described below.

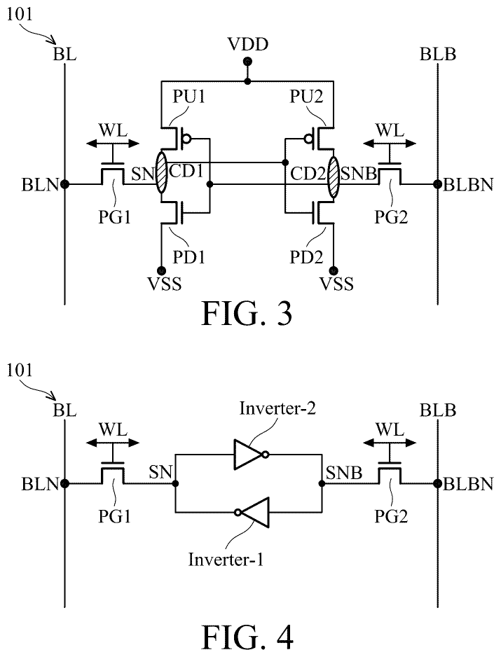

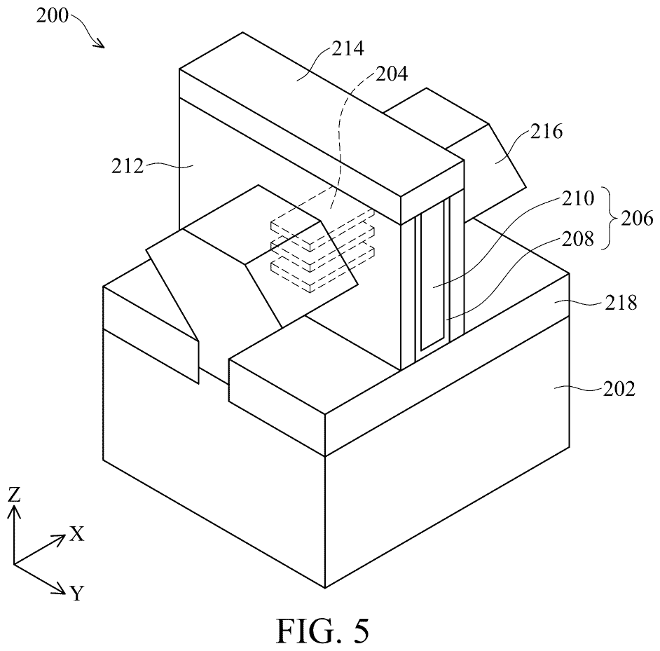

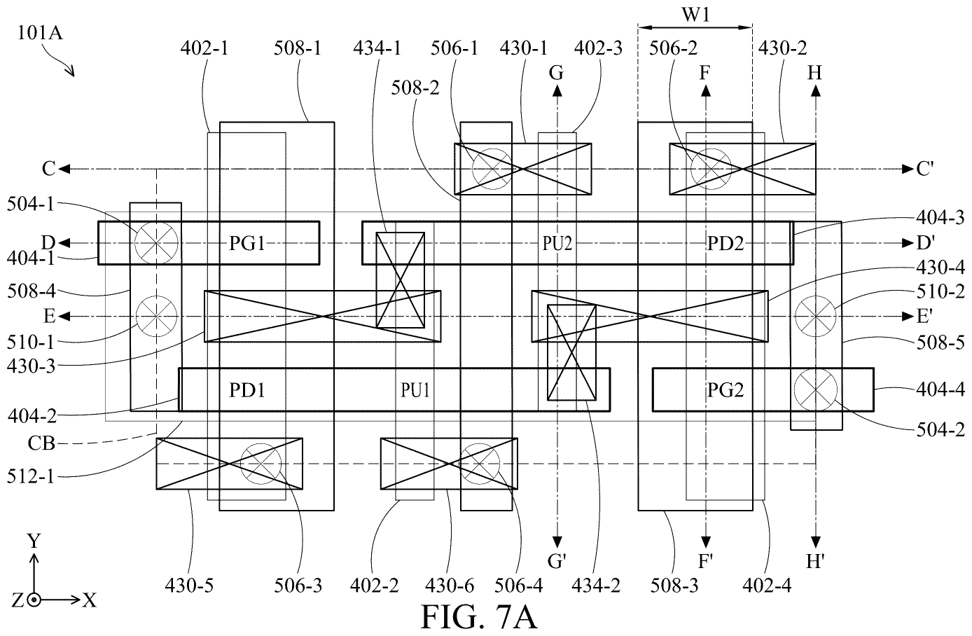

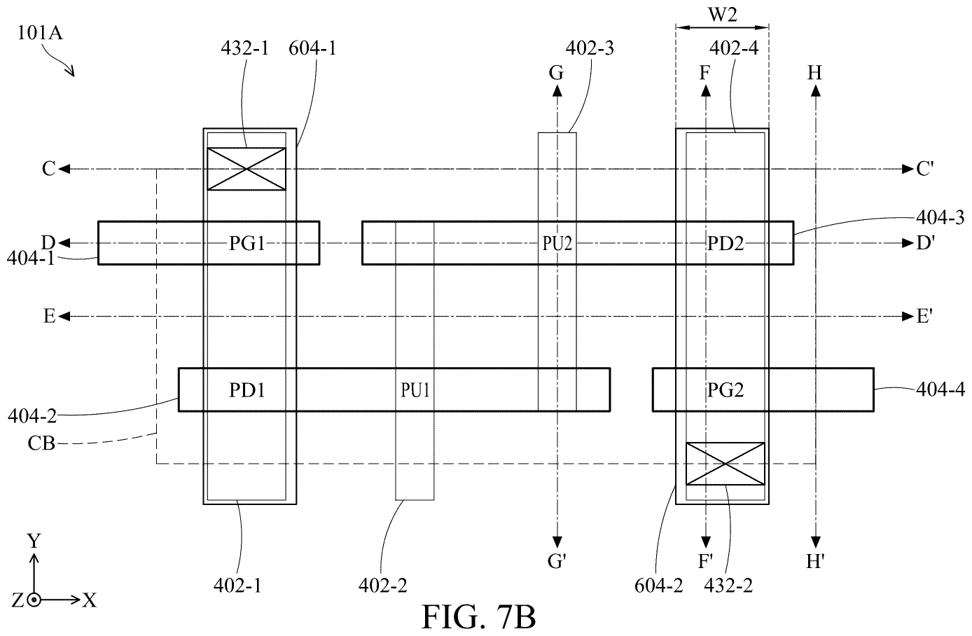

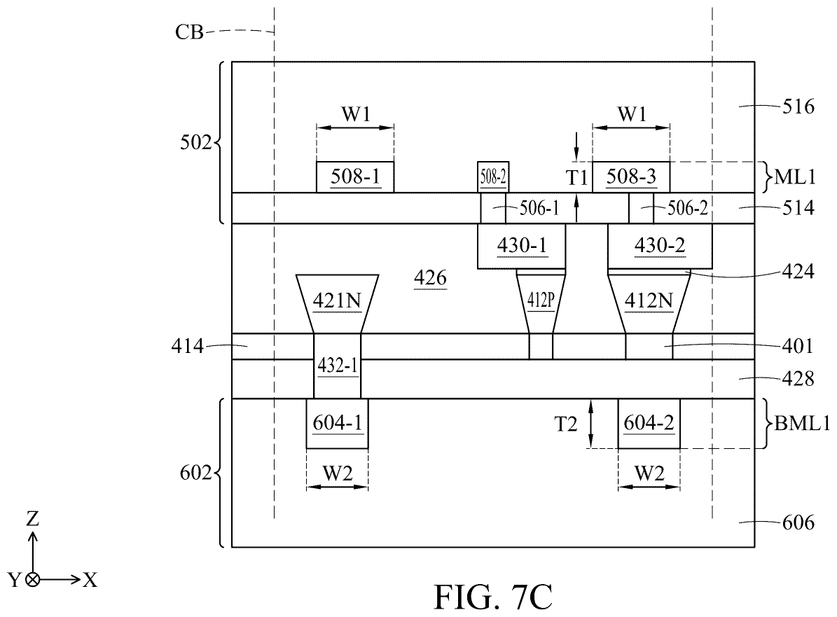

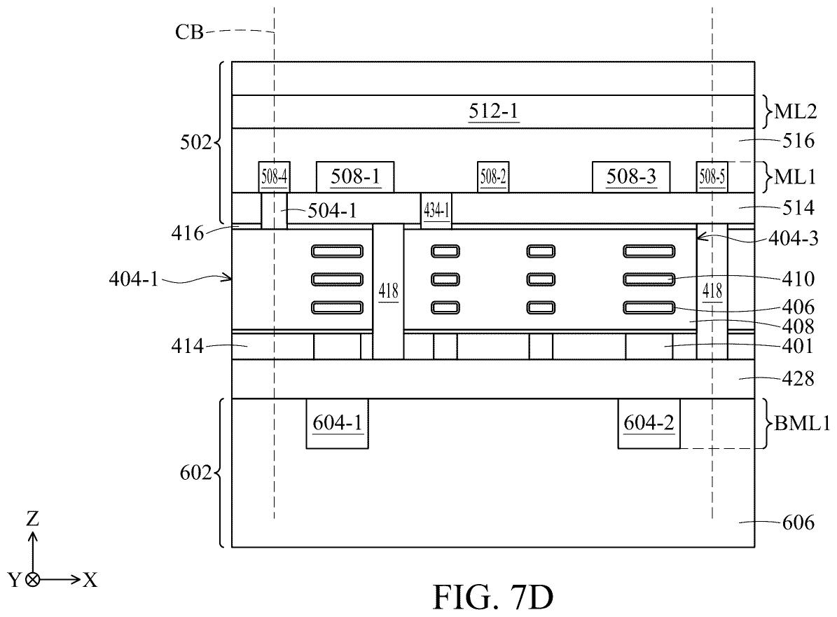

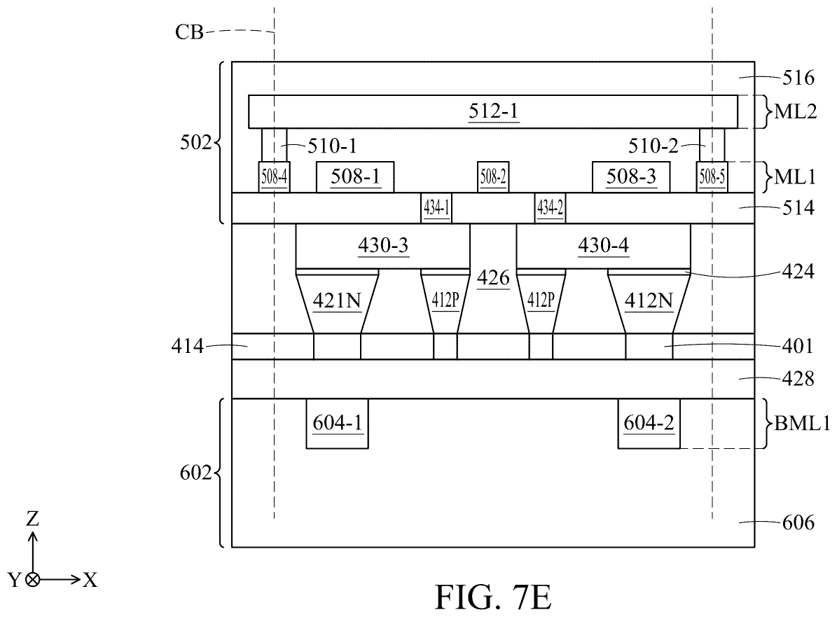

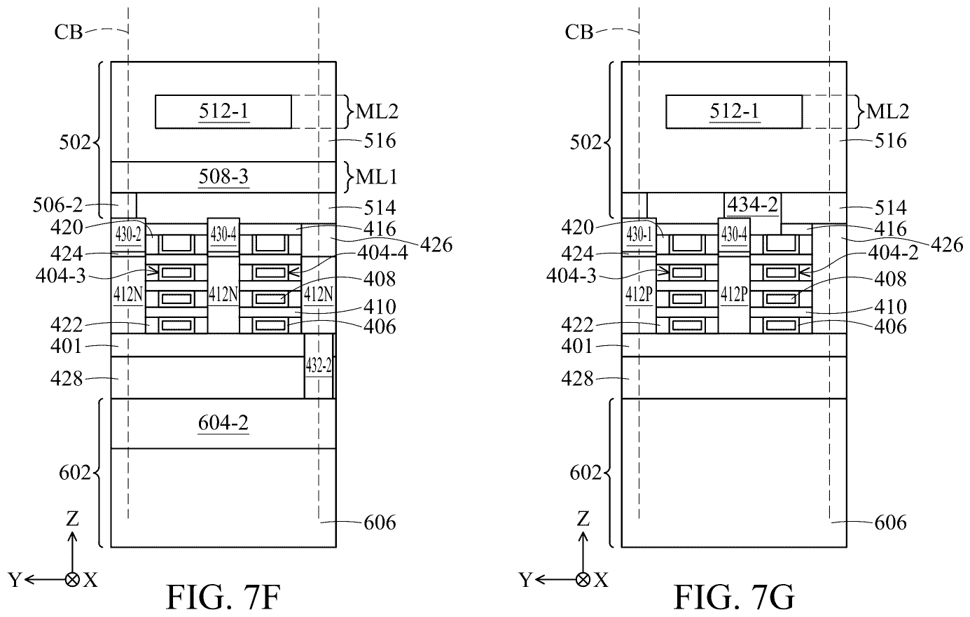

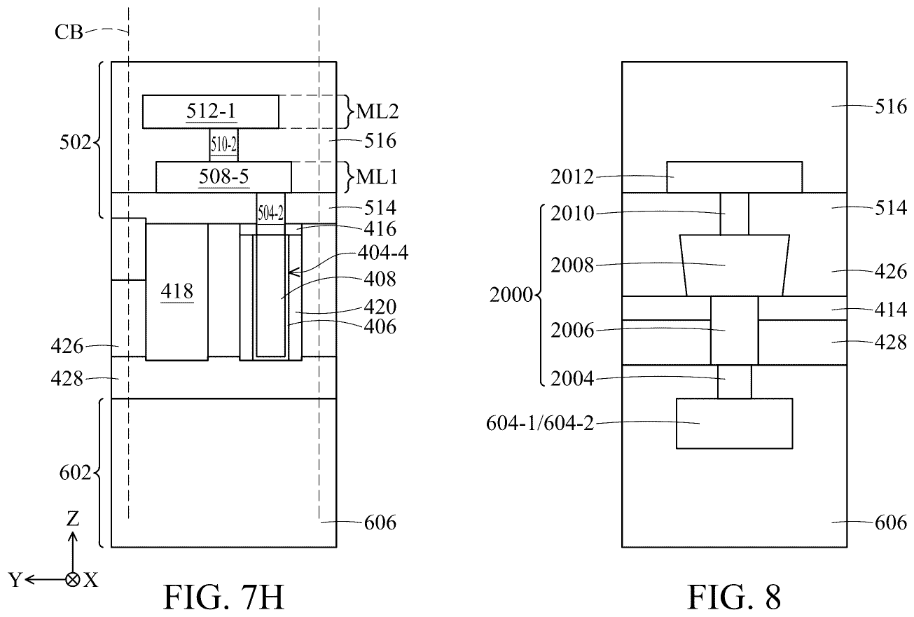

FIG. 3 and FIG. 4 are circuit diagrams of an SRAM circuit that can be implemented in an SRAM cell (e.g., the SRAM cell 101 in FIG. 2) of an array in the memory region 20 of FIG. 1, in accordance with some alternative embodiments of the present disclosure. The circuit diagram of SRAM cell is merely exemplary, and in some embodiments, each of SRAM cells (e.g., SRAM cells 101A to 101K in FIGS. 7A to 18B) in the array is configured with an SRAM circuit similar to the SRAM cell 101 and as shown in FIG. 3 and FIG. 4. For example, each of SRAM cells has a storage portion that includes a cross-coupled pair of inverters (also referred to as a latch), such as an Inverter-1 and an Inverter-2. Inverter-1 includes pull-up transistor PU1 and pull-down transistor PD1, and Inverter-2 includes pull-up transistor PU2 and pull-down transistor PD2. Pass-gate transistor PG1 is connected to an output of Inverter-1 and an input of Inveter-2, and pass-gate transistor PG2 is connected to an output of Inverter-2 and an input of Inverter-1. In operation, pass-gate transistor PG1 and pass-gate transistor PG2 provide access to the storage portion of their respective SRAM cell (i.e., Inverter-1 and Invereter-2) and can also be referred to as access transistors of their respective SRAM cell. Each of SRAM cells (e.g., the SRAM cells 101A to 101K in FIGS. 7A to 18B) is connected to and powered through a first power supply voltage, such as a positive power supply voltage, and a second power supply voltage, such as a ground voltage or a reference voltage (which can be an electrical ground). A gate of pull-up transistor PU1 interposes a source, which is electrically coupled to the first power supply voltage via a voltage node (or voltage source) VDD, and a first common drain (CD1) (i.e., a drain of pull-up transistor PU1 and a drain of pull-down transistor PD1). A gate of pull-down transistor PD1 interposes a source, which is electrically coupled to the second power supply voltage via a voltage node (or voltage source) VSS, and the first common drain. A gate of pull-up transistor PU2 interposes a source, which is electrically coupled to the first power supply voltage via voltage node VDD, and a second common drain (CD-2) (i.e., a drain of pull-up transistor PU2 and a drain of pull-down transistor PD2). A gate of pull-down transistor PD2 interposes a source, which is electrically coupled to the second power supply voltage via voltage node VSS, and the second common drain. The first common drain provides a storage node SN that stores data in true form, and the second common drain provides a storage node SNB that stores data in complementary form, or vice versa, in some embodiments. The gate of pull-up transistor PU1 and the gate of pull-down transistor PD1 are coupled together and to the second common drain SD2, and the gate of pull-up transistor PU2 and the gate of pull-down transistor PD2 are coupled together and to the first common drain SD1. A gate of pass-gate transistor PG1 interposes a drain connected to a bit line node BLN, which is electrically coupled to a bit line BL, and a source, which is electrically coupled to the first common drain CD1. A gate of pass-gate transistor PG2 interposes a drain connected to a complementary bit line node BLBN, which is electrically coupled to a complementary bit line BLB, and a source, which is electrically coupled to the second common drain CD2. Gates of pass-gate transistors PG1, PG2 are connected to and controlled by a word line WL, which allows selection of a respective SRAM cell, such as the SRAM cell 101A, for reading and/or writing. In some embodiments, pass-gate transistors PG1, PG2 provide access to storage nodes SN, SNB, respectively, each of which can store a bit (e.g., a logical 0 or a logical 1), during read operations and/or write operations. For example, pass-gate transistors PG1, PG2 couple storage nodes SN, SNB, respectively, to bit line BL and bit line bar BLB in response to voltage applied to gates of pass-gate transistors PG1, PG2 by word line WL. In some embodiments, SRAM cells are single-port SRAMs. In some embodiments, SRAM cells are configured as multi-port SRAMs, such as dual-port SRAMs, and/or with more or less transistors than depicted, such as 8T SRAMs. FIG. 3 and FIG. 4 have been simplified for the sake of clarity to better understand the inventive concepts of the present disclosure. Additional features can be added in the SRAM circuits of FIG. 3 and FIG. 4, and some of the features described herein can be replaced, modified, or eliminated in other embodiments of the SRAM circuits of FIG. 3 and FIG. 4.

Each of the SRAM cells discussed above is constructed by transistors, such that the SRAM cells herein may also be referred to as transistor cells. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 5. However, it should be understood that the application should not be limited to a particular type of device, except as specifically claimed.

Referring to FIG. 5, a perspective view of an exemplary GAA transistor 200 is illustrated. The GAA transistor 200 is formed over a substrate 202. The substrate 202 may contains a semiconductor material, such as bulk silicon (Si). In some embodiments, after the resultant GAA transistor 200 is formed, the substrate 202 may be removed by a suitable process (e.g., a chemical mechanical polishing (CMP) process) for forming back-side interconnection.

The GAA transistor 200 also includes one or more nanostructures 204 (dash lines) extending in an X-direction and vertically stacked (or arranged) in a Z-direction. More specifically, the nanostructures 204 are spaced from each other in the Z-direction. In some embodiments, the nanostructures 204 may also be referred to as channels, channel layers, nanosheets, or nanowires.

The GAA transistor 200 further includes a gate structure 206 including a gate dielectric layer 208 and a gate electrode layer 210. The gate dielectric layer 208 wraps around the nanostructures 204 and the gate electrode layer 210 wraps around the gate dielectric layer 208 (not shown in FIG. 5, may refer to FIGS. 7D, 7F, and 7G). As shown in FIG. 5, gate spacers 212 are on sidewalls of the gate structure 206 and over the nanostructures 204 (not shown in FIG. 2, may refer to FIGS. 7F and 7G). A gate top dielectric layer 214 is over the gate dielectric layer 208, the gate electrode layer 210, and the nanostructures 204. The gate top dielectric layer 214 is used for contact etch protection layer.

The GAA transistor 200 further includes source/drain features 216. As shown in FIG. 5, two source/drain features 216 are on opposite sides of the gate structure 206. The nanostructures 204 (dash lines) extends in the X-direction to connect one source/drain feature 216 to the other source/drain feature 216. The source/drain features 216 may also be referred to as source/drain, or source/drain regions. In some embodiments, source/drain feature(s) may refer to a source or a drain, individually or collectively dependent upon the context.

Isolation feature 218 is over the substrate 202 and under the gate dielectric layer 208, the gate electrode layer 210, and the gate spacers 212. The isolation feature 218 is used for isolating the GAA transistor 200 from other devices. In some embodiments, the isolation feature 218 may include different structures, such as shallow trench isolation (STI) structure, deep trench isolation (DTI) structure. Therefore, the isolation feature 218 is also referred as to as a STI feature or DTI feature.

Generally, interconnection of devices and transistor cells are disposed over or at front-side of transistors to form desired circuit routing. As transistors and transistor cells continue to be scaled down, space for interconnection routing is also decreased. In order to achieve desired circuit routing, metal conductor width and conductor-to-conductor space are decreased, thereby increasing resistance and parasitic capacitance to impact performance of devices and transistor cells. In some embodiments of present disclosure, a part of interconnection of devices and transistor cells is disposed under or at back-side of transistors to improve upon the above issue.

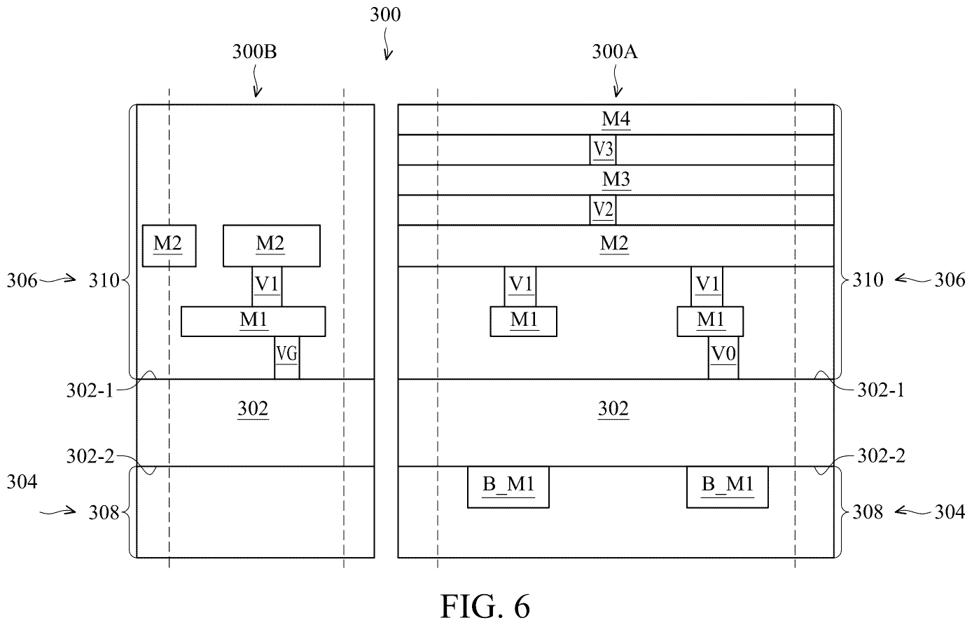

FIG. 6 shows a cross sectional view of a semiconductor device 300 for illustrating front-side interconnection and back-side interconnection, in accordance with some embodiments of the present disclosure. FIG. 6 also illustrates X-cut cross sectional view 300A and Y-cut cross sectional view 300B of the semiconductor device 300. The semiconductor device 300 has a device region 302 (also referred to as a device layer), a back-side interconnection structure 304, and a front-side interconnection structure 306. The device region 302 is the region where the transistors and main features of SRAM cells (e.g., the SRAM cells 101A to 101H in FIGS. 7A to 15F) are located, such as gate structures, nanostructures, source/drain features, and contact features. The device region 302 has a front-side 302-1 and a back-side 302-2. The back-side interconnection structure 304 is under the device region 302 or at the back-side 302-2 of the device region 302, and the front-side interconnection structure 306 is over the device region 302 or at the front side 302-1 of the device region 302.

As shown in FIG. 6, the back-side interconnection structure 304 includes inter-metal dielectric (IMD) 308 and metal conductors B_M1. The front-side interconnection structure 306 includes IMD 310, vias VG, V0, V1, V2, and V3, and metal conductors M1, M2, M3, and M4. The vias and metal conductors in the IMD 308 and 310 electrically couples various transistors and/or components (for example, gate structures, source/drain features, resistors, capacitors, and/or inductors) in the device region 302, such that the various devices and/or components can operate as specified by design requirements of transistor cells (e.g., logic cells and memory cells). It should be noted that there may be more vias and metal conductors in the IMD 308 and 310 for connections. The IMD 308 and 310 may be multilayer structure, such as one or more dielectric layers.

Since the back-side interconnection structure 304 is at the back-side 302-2 of the device region 302, the IMD 308 and the metal conductors B_M1 may also be referred to as back-side IMD and back-side metal conductors, respectively. Since the front-side interconnection structure 306 is at the front-side 302-1 of the device region 302, the IMD 310, the vias VG, V0, V1, V2, and V3, and the metal conductors M1, M2, M3, and M4 may also be referred to as front-side IMD, front-side vias, and front-side metal conductors, respectively. In some embodiments, the via VG are connected to the gate structures (specifically, the gate electrode layers) of the transistors. Therefore, the via VG are also referred to as gate vias or front-side gate via.

The formation of the back-side interconnection structure 304 may include removing the substrate (if present) by CMP process, forming a back-side dielectric layer (not shown) under the device region 302 (or the back-side 302-2 of the device region 302), forming back-side contacts (not shown) connected to the source/drain features in the device region 302 in the back-side dielectric layer, forming a dielectric layer of the IMD 308 under the back-side dielectric layer, forming back-side first level metal conductors (e.g., the metal conductors B_M1) in the dielectric layer, and forming protection layer (may be multiple layers and include dielectric layers, poly layers, or combination) under the fourth dielectric layer. The formation of the front-side interconnection structure 306 is similar to that of back-side interconnection structure 304, in which the difference is that the formation processes of the front-side interconnection structure 306 are performed at the front-side 302-1 of the device region 302, and may not be described in detail herein.

FIGS. 7A and 7B illustrate top views (or layouts) of an SRAM cell 101A in a semiconductor device that can be one embodiment of the SRAM cells 101 implemented in the array 100 discussed above, in accordance with some embodiments of the present disclosure. FIG. 7A illustrates the features in a device region (including transistors) and a front-side interconnection structure (including vias and metal conductors), and FIG. 7B illustrates the features in the device region and a back-side interconnection structure.

FIG. 7C illustrates an X-Z cross-sectional view of the SRAM cell 101A in the semiconductor device along a line C-C′ in FIGS. 7A and 7B, in accordance with some embodiments of the present disclosure. FIG. 7D illustrates an X-Z cross-sectional view of the SRAM cell 101A in the semiconductor device along a line D-D′ in FIGS. 7A and 7B, in accordance with some embodiments of the present disclosure. FIG. 7E illustrates an X-Z cross-sectional view of the SRAM cell 101A in the semiconductor device along a line E-E′ in FIGS. 7A and 7B, in accordance with some embodiments of the present disclosure. FIG. 7F illustrates a Y-Z cross-sectional view of the SRAM cell 101A in the semiconductor device along a line F-F′ in FIGS. 7A and 7B, in accordance with some embodiments of the present disclosure. FIG. 7G illustrates a Y-Z cross-sectional view of the SRAM cell 101A in the semiconductor device along a line G-G′ in FIGS. 7A and 7B, in accordance with some embodiments of the present disclosure. FIG. 7H illustrates a Y-Z cross-sectional view of the SRAM cell 101A in the semiconductor device along a line H-H′ in FIGS. 7A and 7B, in accordance with some embodiments of the present disclosure.

As shown in FIGS. 7A and 7B, the SRAM cell 101A has a cell boundary CB indicated by the dotted rectangular box and constructed by two cell long boundaries in the X-direction and two cell short boundaries in the Y-direction. In some embodiments, the cell boundary CB has a rectangular shape, such that the cell boundary CB may be referred to as a rectangular cell boundary extending lengthwise in the X-direction, as shown in FIGS. 7A and 7B. Such SRAM cells 101A are arranged in rows along the X-direction and in columns along the Y-direction to form an array of the SRAM cells. In that regard, the length of the cell long boundaries is also the pitch of the array of SRAM cells 101A along the X-direction, and the length of the cell short boundaries is also the pitch of the array of SRAM cells 101A along the Y-direction.

The SRAM cell 101A includes active areas, such as active areas 402-1 to 402-4, (may be collectively referred to as the active areas 402) that extend lengthwise in the Y-direction. Each of active areas 402 includes channel regions, source regions, and drain regions (where source regions and drain regions are collectively referred to as source/drain regions herein) of transistors.

The SRAM cell 101A further includes gate structures, such as gate structures 404-1 to 404-4 (may be collectively referred to as the gate structures 404) that extend lengthwise in the X-direction. The X-direction and the Y-direction are perpendicular. The gate structures 404-1 to 404-4 are disposed over the channel regions of the respective active areas 402-1 to 402-4 (i.e., (vertically stacked) nanostructures 410) and disposed between respective source/drain regions of the active areas 402-1 to 402-4 (i.e., source/drain features 412N and 412P). In some embodiments, the gate structures 404-1 to 404-4 wrap and/or surround suspended, vertically stacked nanostructures 410 in the channel regions of the active areas 402-1 to 402-4, respectively (as shown in FIGS. 7D, 7F, and 7G).

As shown in FIGS. 7A and 7B, in the SRAM cell 101A, the gate structure 404-1 extends across the active area 402-1 in the top view and engages the active area 402-1 to form the pass-gate transistor PG1; the gate structure 404-2 extends across the active areas 402-1 and 402-2 in the top view and engages the active area 402-1 and 402-2 to form the pull-down transistor PD1 and the pull-up transistor PU1 respectively; the gate structure 404-3 extends across the active areas 402-3 and 402-4 in the top view and engages the active area 402-3 and 402-4 to form the pull-up transistor PU2 and the pull-down transistor PD2 respectively; and the gate structure 404-4 extends across the active area 402-4 in the top view and engages the active area 402-4 to form the pass-gate transistor PG2.

Furthermore, as shown in FIGS. 7A, 7B, and 7D, the pull-down transistor PD1 and the pull-up transistor PU1 are arranged in the X-direction and share the gate structure 404-2, and the pull-down transistor PD2 and the pull-up transistor PU2 are arranged in the X-direction and share the gate structure 404-3, such that the gate structure 404-2 and the gate structure 404-3 are also referred to as common gates or shared gate structures. In some embodiments, the pass-gate transistor PG1 and the pull-down transistor PD1 are arranged in the Y-direction and share the active area 402-1, and the pass-gate transistor PG2 and the pull-down transistor PD2 are arranged in the Y-direction and share the active area 402-4.

Similar to the substrate 202 discussed above, the SRAM cell 101A further includes a substrate (or a semiconductor substrate) 401, over which the various features are formed, such as the gate structures 404-1 to 404-4. The substrate 401 may contains a semiconductor material, such as bulk silicon (Si). In some other embodiments, the substrate 401 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Alternatively, the substrate 401 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

In some embodiments, the n-type well NW and p-type wells PW are formed in or on the substrate 401. In the present embodiment, the p-type wells PW are p-type doped regions configured for n-type transistors (e.g., the pass-gate transistors PG1 and PG2, and the pull-down transistors PD1 and PD2), and the n-type well NW are n-type doped regions configured for p-type transistors (e.g., the pull-up transistors PU1 and PU2). The n-type well is doped with n-type dopants, such as phosphorus, arsenic, other n-type dopant, or a combination thereof. The p-type wells are doped with p-type dopants, such as boron, indium, other p-type dopant, or a combination thereof. In some implementations, the substrate 401 includes doped regions formed with a combination of p-type dopants and n-type dopants. The various n-type wells and/or p-type wells can be formed directly on and/or in the substrate 401, for example, providing a p-well structure, an n-well structure, a dual-well structure, a raised structure, or a combination thereof. An ion implantation process, a diffusion process, and/or other suitable doping process can be performed to form the various wells.

Similar to the isolation feature 218 discussed above, the SRAM cell 101A further includes an isolation feature (or isolation structure) 414. The isolation feature 414 is formed between the active areas 402. More specifically, the active areas 402 include the portions of the substrate 401 under the channel regions and the source/drain regions, as shown in FIGS. 7C, 7D, and 7E, and the isolation feature 414 is formed between the portions of the substrate 401. In some aspects, the isolation feature 414 is formed around the active areas 402 (specifically, the portions of the substrate 401 under the channel regions and the source/drain regions). In some embodiments, the gate structures 404 are also formed over and interfacing a top surface of the isolation feature 414. For example, as shown FIG. 7D, the gate structures 404-1 and 404-3 are over and interface a top surface of the isolation feature 414.

The isolation feature 414 may include silicon oxide, silicon nitride, silicon oxynitride, other suitable isolation material (for example, including silicon, oxygen, nitrogen, carbon, or other suitable isolation constituent), or combinations thereof. The isolation feature 414 may include different structures, such as shallow trench isolation (STI) structures, deep trench isolation (DTI) structures, and/or local oxidation of silicon (LOCOS) structures. In some embodiments, STI features include a multi-layer structure that fills the trenches, such as a silicon nitride including layer disposed over a thermal oxide including liner layer. In another example, STI features include a dielectric layer disposed over a doped liner layer (including, for example, boron silicate glass (BSG) or phosphosilicate glass (PSG)). In yet another example, STI features include a bulk dielectric layer disposed over a liner dielectric layer, where the bulk dielectric layer and the liner dielectric layer include materials depending on design requirements.

Each of the transistors in the SRAM cell 101A (e.g., the pass-gate transistors PG1 and PG2, the pull-down transistors PD1 and PD2, and the pull-up transistors PU1 and PU2) includes nanostructures 410 similar to the nanostructures 204 discussed above. As shown in FIGS. 7D, 7F, and 7G, the nanostructures 410 are suspended. In some embodiments, three nanostructures 410 are vertically stacked (or vertically arranged) from each other in the Z-direction for one transistor. However, there may be another appropriate number of nanostructures in one transistor. For example, there may be from 2 to 6 nanostructures 410 in one transistor.

The nanostructures 410 further extend lengthwise in the Y-direction (FIGS. 7A, 7F, and 7G) and widthwise in the X-direction (FIGS. 7A and 7D). In some embodiments, a width of the nanostructures 410 in the active areas 402-1 and 402-4 in the X-direction is greater than a width of the nanostructures 410 in the active areas 402-2 and 402-3, as shown in FIGS. 7A and 7D. As shown in FIG. 7D, in each of the transistors in the SRAM cell 101A, three nanostructures 410 are spaced apart from each other in the Z-direction.

The nanostructures 410 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 410 include silicon for n-type transistors. In other embodiments, the nanostructures 410 include silicon germanium for p-type transistors. In some embodiments, the nanostructures 410 are all made of silicon, and the type of the transistors depend on work function metal layer wrapping around the nanostructures 410. In some embodiments, the nanostructures 410 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

Each of the gate structures 404-1 to 404-4 has a gate dielectric layer 406 and a gate electrode layer 408. The gate dielectric layers 406 wrap around each of the nanostructures 410, and the gate electrode layer 408 wrap around the gate dielectric layer 406 and the nanostructures 410. In some embodiments, the gate structures 404 each further includes an interfacial layer (such as having silicon dioxide, silicon oxynitride, or other suitable materials) between the gate dielectric layer 406 and the nanostructures 410.

The gate dielectric layers 406 may include oxide with nitrogen doped dielectric material (initial layer) combined with metal content high-K dielectric material (K value (dielectric constant)>13). For example, gate dielectric layers 406 may include hafnium oxide (HfO₂), which has a dielectric constant in a range from about 18 to about 40. Alternatively, the gate dielectric layers 406 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. The gate dielectric layers 406 may be formed by chemical oxidation, thermal oxidation, ALD, CVD, and/or other suitable methods.

The gate electrode layer 408 is formed to wrap around the gate dielectric layer 406 and the center portions of the nanostructures 410, as shown in FIGS. 7F and 7G. In some embodiments, the gate electrode layer 408 may include an n-type work function metal layer for n-type transistor (e.g., the pass-gate transistors PG1 and PG2, and the pull-down transistors PD1 and PD2) or a p-type work function metal layer for p-type transistor (e.g., the pull-up transistors PU1 and PU2), in accordance with some embodiments of the present disclosure.

In an embodiment, the n-type work function metal layer is a material such as Ti, Al, Ag, Mn, Zr, TiAl, TiAIC, TaC, TaCN, TaSiN, TaAl, TaAIC, TiAIN, other suitable n-type work function materials, or combinations thereof. For example, the n-type work function metal layer may be deposited utilizing ALD, CVD, or the like. However, any suitable materials and processes may be utilized to form the n-type work function metal layer.

In an embodiment, the p-type work function metal layer is a material such as TiN, TaN, Ru, Mo, Al, WN, ZrSi₂, MoSi₂, TaSi₂, NiSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, other suitable p-type work function materials, combinations of these, or the like. Additionally, the p-type work function metal layer may be deposited using a deposition process such as ALD, CVD, or the like, although any suitable deposition process may be used.

In some embodiments, the gate electrode layer 408 may include a single layer or alternatively a multi-layer structure. In some embodiments, the gate electrode layer 408 may further include a capping layer, a barrier layer, and a fill material (not shown). The capping layer may be formed adjacent to the gate dielectric layers 406 and may be formed from a metallic material such as TaN, Ti, TiAIN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent the capping layer, and may be formed of a material different from the capping layer. For example, the barrier layer may be formed of a material such as one or more layers of a metallic material such as TiN, TaN, Ti, TiAIN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The SRAM cell 101A further includes gate top dielectric layers 416 over the gate dielectric layers 406, the gate electrode layer 408, the nanostructures 410, and gate spacers 420. The gate top dielectric layers 416 are similar to the gate top dielectric layer 214 discussed above. The gate top dielectric layer 416 is used for contact etch protection layer. The material of gate top dielectric layer 416 is selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), combinations thereof, or other suitable material.

The SRAM cell 101A further includes the gate spacers 420 on sidewalls of the gate structures 404 and over the nanostructures 410, as shown in FIGS. 7F and 7G. More specifically, the gate spacers 420 are over the nanostructures 410 and on top sidewalls of the gate structures 404, and thus are also referred to as gate top spacers or top spacers. The gate spacers 420 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 420 may include a single layer or a multi-layer structure.

As shown in FIGS. 7F and 7G, the SRAM cell 101A further includes inner spacers 422 on the sidewalls of the gate structures 404 and below the topmost nanostructures 410 and the gate spacers 420. Furthermore, the inner spacers 422 are laterally between the source/drain features 412N (or 412P) and the gate structures 404. The inner spacers 422 are also vertically between adjacent nanostructures 410. The inner spacers 422 may include a dielectric material having higher K value (dielectric constant) than the gate spacers 420 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the thickness of the gate spacers 420 in the Y-direction and the thickness of the inner spacers 422 in the Y-direction are the same. In other embodiments, the thickness of the gate spacers 420 in the Y-direction is less than the thickness of the inner spacers 422 in the Y-direction due to the gate spacers 420 being trimmed during sequent processes for forming source/drain contacts.

As shown in FIGS. 7D and 7H, the SRAM cell 101A further includes gate end dielectrics 418 at ends of the gate structures 404. The gate end dielectric structures 418 are used for separating the gate structures 404 aligned in the X-direction. For example, the gate end dielectrics 418 separate the gate structures 404-1 and 404-3, as shown in FIG. 7D. The gate end dielectric structures 418 are also used for separating the SRAM cell 101A from other device (e.g., SRAM cells or logic cells) in the X-direction. Furthermore, as shown in FIG. 7D, the gate end dielectric structure 418 are in contact with the gate structures 404 in the X-direction. As shown in FIG. 7D, the gate end dielectric structures 418 further extend into the isolation feature 414 in the Z-direction. In some embodiments, bottom surfaces of the gate end dielectric structures 418 are lower than bottom surfaces of the gate structures 404, as shown in FIG. 7D.

The material of the gate end dielectric structures 418 can be single dielectric layer or multiple layers and selected from a group consisting of Si₃N₄, nitride based dielectric layer, SiO₂, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or combinations thereof.

Referring to FIGS. 7C and 7E to 7G, the SRAM cell 101A further includes source/drain features 412N and source/drain features 412P in the source/drain regions of the active areas 402. The source/drain features 412N are disposed on opposite sides of the respective gate structure 404 and connected by the nanostructures 410 to form n-type transistor (e.g., the pass-gate transistors PG1 and PG2, the pull-down transistors PD1 and PD2). Similarly, the source/drain features 412P are disposed on opposite sides of the respective gate structure 404 and connected by the nanostructures 410 to form p-type transistor (e.g., the pull-up transistors PU1 and PU2). In some aspects, the source/drain features 412N/412P are disposed on opposite sides of the respective nanostructures 410. More specifically, the source/drain features 412N/412P are attached and electrically connected to the nanostructures 410 in the Y-direction, as shown in FIGS. 7F and 7G. Furthermore, every two adjacent transistors in the Y direction share one source/drain feature 412N/412P, as shown in FIGS. 7F and 7G.

The source/drain features 412N and 412P may be formed by using an epitaxial growth process. In some embodiments, the source/drain features 412N may include epitaxially-grown material selected from a group consisting of SiP, SiC, SiPC, SiAs, Si, or a combination thereof. In some embodiments, the epitaxially-grown material of the source/drain features 412N may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 412N for n-type transistors may be respectively referred to as n-type features and n-type source/drain features.

In some embodiments, the source/drain features 412P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 412P may be doped with p-type dopants (such as boron, indium, other p-type dopant, or combinations thereof) having a doping concentration in a range from about 1×10¹⁹/cm³ to 6×10²⁰/cm³. In some embodiments, the source/drain features 412P for p-type transistors may be respectively referred to as p-type source/drain features.

As shown in FIGS. 7C and 7E to 7G, the SRAM cell 101A further includes silicide features 424 over the source/drain features 412N and 412P. The silicide features 424 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

Referring to FIGS. 7A to 7C and 7E to 7G, the SRAM cell 101A further includes source/drain contacts 430 (including source/drain contacts 430-1 to 430-6) in an inter-layer dielectric (ILD) layer 426 and source/drain contacts 432 (including source/drain contacts 432-1 and 432-2) in a dielectric layer 428. The ILD layer 426 are formed over the isolation feature 414, as shown in FIS. 7C and 7E. In some embodiments, the ILD layer 426 surround the source/drain contacts 430, and the dielectric layer 428 surround the source/drain contacts 432. Furthermore, the ILD layer 426, the dielectric layer 428, and the isolation feature 414 may have a dielectric constant that is about 3 to about 5. As shown in FIG. 7A, the source/drain contacts 430 and 432 extend lengthwise in the X-direction. The source/drain contacts 430 are self-aligned source/drain contacts. This means that the source/drain contacts 430 are formed by using the gate spacers 420 as mask. Therefore, the source/drain contacts 430 are in direct contact with the gate spacers 420, as shown in FIGS. 7F and 7G. In some embodiments, the gate spacers 420 are trimmed due to the gate spacers 420 serving as the mask for forming the source/drain contacts 430. Therefore, the thickness of the gate spacers 420 in the Y-direction is less than the thickness of the inner spacers 422 in the Y-direction, as discussed above. In the top view, as shown in FIGS. 7A and 7B, the source/drain contacts 430-1, 430-2, 430-5, 430-6, 432-1, and 432-2 lengthwise overlap the cell boundary CB.

In the top view, as shown in FIGS. 7A and 7B, the source/drain contact 430-1 is adjacent to the gate structure 404-3 (or is adjacent to the pull-up transistor PU2) in the Y-direction; the source/drain contact 430-2 is adjacent to the gate structure 404-3 (or is adjacent to the pull-down transistor PD2) in the Y-direction; the source/drain contact 430-3 is between the gate structures 404-1 and 404-2 (or between the pass-gate transistor PG1 and the pull-down transistor PD1) in the Y-direction; the source/drain contact 430-4 is between the gate structures 404-3 and 404-4 (or between the pass-gate transistor PG2 and the pull-down transistor PD2) in the Y-direction; the source/drain contact 430-5 is adjacent to the gate structure 404-2 (or is adjacent to the pull-down transistor PD1) in the Y-direction; the source/drain contact 430-6 is adjacent to the gate structure 404-2 (or is adjacent to the pull-up transistor PU1) in the Y-direction; the source/drain contact 432-1 is adjacent to the gate structure 404-1 (or is adjacent to the pass-gate transistor PG1) in the Y-direction; and the source/drain contact 432-2 is adjacent to the gate structure 404-4 (or is adjacent to the pass-gate transistor PG2) in the Y-direction.

Furthermore, each of the source/drain contacts 430 is over and electrically connected to the respective source/drain features 412N/412P and each of the source/drain contacts 432 is under and electrically connected to the respective source/drain features 412N/412P. Specifically, as shown in FIGS. 7A, 7C, 7E, and 7G, the source/drain contact 430-1 is over and electrically connected to the source/drain feature 412P of the pull-up transistor PU2; the source/drain contact 430-2 is over and electrically connected to the source/drain feature 412N of the pull-down transistor PD2; the source/drain contact 430-3 is over and electrically connected to the source/drain feature 412N shared by the pass-gate transistor PG1 and pull-down transistor PD1 (also referred to as common source/drain or common drain (CD1)) and the source/drain feature 412P of the pull-up transistor PU1, which corresponds to the storage node SN shown in FIG. 3; the source/drain contact 430-4 is over and electrically connected to the source/drain feature 412N shared by the pass-gate transistor PG2 and pull-down transistor PD2 (also referred to as common source/drain or common drain (CD2)) and the source/drain feature 412P of the pull-up transistor PU2, which corresponds to the storage node SNB shown in FIG. 3; the source/drain contact 430-5 is over and electrically connected to the source/drain feature 412N of the pull-down transistor PD1; and the source/drain contact 430-6 is over and electrically connected to the source/drain feature 412P of the pull-up transistor PU1. As shown in FIGS. 7B, 7C, 7E, and 7G, the source/drain contact 432-1 is under and electrically connected to the source/drain feature 412N of the pass-gate transistor PG1; and the source/drain contact 432-2 is under and electrically connected to the source/drain feature 412N of the pass-gate transistor PG2.

In some embodiments, the source/drain contacts 430 may be referred to as front-side source/drain contacts due to the source/drain contacts 430 being disposed over the source/drain features 412N/412P. In some embodiments, the source/drain contacts 432 may be referred to as back-side source/drain contacts due to the source/drain contacts 432 being disposed under the source/drain features 412N/412P.

The SRAM cell 101A further includes butted contacts 434-1 and 434-2. As shown in FIGS. 7A, 7D, 7E, and 7G, the butted contact 434-1 is over the source/drain contact 430-3 and the gate structure 404-3, and the butted contact 434-2 is over the source/drain contact 430-4 and the gate structure 404-2. In some embodiments, the butted contact 434-1 electrically connects the source/drain contact 430-3 to the gate structure 404-3 and the butted contact 434-2 electrically connects the source/drain contact 430-4 to the gate structure 404-2. The butted contacts 434-1 and the source/drain contact 430-3 may correspond to the storage node SN shown in FIG. 2 and the butted contacts 434-2 and the source/drain contact 430-4 may correspond to the storage node SNB shown in FIG. 2.

The source/drain contacts 430 and 432 and the butted contacts 434-1 and 434-2 may each include a conductive material such as Al, Cu, W, Co, Ti, Ta, Ru, Rh, Ir, Pt, TiN, TiAl, TiAIN, TaN, TaC, combinations of these, or the like, although any suitable material may be deposited using a deposition process such as sputtering, CVD, electroplating, electroless plating, or the like. In some embodiments, the source/drain contacts 430 and 432 and the butted contacts 434-1 and 434-2 may each include single conductive material layer or multiple conductive layers. In some embodiments, the conductivity of the source/drain contacts 430 and 432 is greater than that of source/drain features 412N/412P and silicide features 424.

As discussed above, the front-side interconnection structure is over the device region or at the front-side of the device region. The SRAM cell 101A further includes a front-side interconnection structure 502 including gate vias 504 (including gate vias 504-1 and 504-2), vias 506 (including vias 506-1 to 506-4), metal conductors 508 (including metal conductors 508-1 to 508-5), vias 510 (including vias 510-1 and 510-2), a metal conductor 512-1, an ILD layer 514, and an IMD layer 516, which are over (or at the front-side of) the transistors in the SRAM cell 101A (located in the device region, as discussed above) (e.g., the pass-gate transistors PG1 and PG2, the pull-down transistors PD1 and PD2, and the pull-up transistors PU1 and PU2).

The metal conductors 508 are in a (front-side) metal layer ML1 in the IMD layer 516 and extend lengthwise in the Y-direction. The metal conductor 512-1 is in a (front-side) metal layer ML2 in the IMD layer 516 and extends lengthwise in the X-direction. The metal layer ML1 is over the SRAM cell 101A and the metal layer ML2 is over the metal layer ML1, and thus the metal conductors 508 are over the transistors (e.g., the pass-gate transistors PG1 and PG2, the pull-down transistors PD1 and PD2, and the pull-up transistors PU1 and PU2) and the features (including the source/drain contacts 430, the source/drain features 412N/412P, the nanostructures 410, and gate structures 404) of the SRAM cell 101A, and the metal conductor 512-1 is over the metal conductors 508.

The gate vias 504 and vias 506 are in the ILD layer 514, and the vias 510 are in the IMD layer 516. Each of the gate vias 504 in the ILD layer 514 is vertically between and electrically connected to the respective gate structure 404 and the respective metal conductor 508. Each of the vias 506 in the ILD layer 514 is vertically between and electrically connected to the respective source/drain contact 430 and the respective metal conductor 505. Each of the vias 510 in the IMD layer 516 is vertically between and electrically connected to the respective metal conductor 508 and the respective metal conductor 512-1. In some embodiments, the gate vias 504, the vias 506, and the vias 510 may have circular shape in the top view. In other embodiments, the gate vias 504, the vias 506, and the vias 510 may have a rectangular shape in the top view.

Furthermore, as shown in FIG. 7A, the metal conductors 508-4 and 508-5 lengthwise overlap the cell boundary CB in the top view. In some embodiments, the gate vias 504 and vias 506 and 510 overlap the cell boundary CB in the top view, as shown in FIG. 7A. The gate vias 504, the vias 506, the metal conductors 508, the vias 510, and the metal conductor 512-1 may be respectively similar to the via VG, the via V0, the metal conductors M1, the vias V1, and the metal conductors M2 discussed above. The vias 506 and 510, the gate vias 504, the metal conductors 508 and 512-1, the ILD layer 514, and IMD layer 516 may also be referred to as front-side vias, front-side gate vias, front-side metal conductors, front-side ILD layer, and front-side IMD layer, respectively.

In some embodiments, the metal conductor 512-1 serves as the word-line that is electrically connected to a controller (e.g., the controller 103 discussed above) and electrically connected to the gate structures (more specifically, the gate electrode layers) of the pass-gate transistors in the same row of the array of the SRAM cell. As shown in FIGS. 7A to 7H, in the SRAM cell 101A, the metal conductor 512-1 is over the pass-gate transistor PG1 and PG2. The metal conductor 512-1 is electrically connected to the gate structure 404-1 of the pass-gate transistor PG1 through the via 510-1, the metal conductor 508-4, and the gate via 504-1, and is electrically connected to the gate structure 404-4 of the pass-gate transistor PG2 through the via 510-2, the metal conductor 508-5, and the gate via 504-2. In some embodiments, the metal conductor 512-1 may be referred to as (front-side) word-line conductor. In some embodiments, the metal conductors 508-4 and 508-5 may be referred to as word-line landing pads.

In some embodiments, the metal conductors 508-1 and 508-3 serve as the VSS lines that are electrically coupled to a voltage node or voltage source (not shown) (e.g., the voltage node (or voltage source) VSS discussed above) and electrically connected to the source/drain features of the pull-down transistors in the same column of the array of the SRAM cells. As shown in FIGS. 7A to 7H, in the SRAM cell 101A, the metal conductor 508-1 and 508-3 are respectively over the pull-down transistor PD1 and PD2. The metal conductor 508-1 is electrically connected to the source/drain features 412N of the pull-down transistor PD1 through the via 506-3 and the source/drain contact 430-5; and the metal conductor 508-3 is electrically connected to the source/drain features 412N of the pull-down transistor PD2 through the via 506-2 and the source/drain contact 430-2. In some embodiments, the metal conductors 508-1 and 508-3 may be referred to as (front-side) VSS conductors or (front-side) VSS lines.

In some embodiments, the metal conductor 508-2 serves as the VDD line that is electrically coupled to a voltage node or voltage source (not shown) (e.g., the voltage node (or voltage source) VDD discussed above) and electrically connected to the source/drain features of the pull-up transistors in the same column of the array of the SRAM cells. As shown in FIGS. 7A to 7H, in the SRAM cell 101A, the metal conductor 508-2 is over the pull-up transistor PU1 and PU2. Furthermore, the metal conductor 508-2 is between the metal conductors 508-1 and 508-3 in the X-direction. The metal conductor 508-2 is electrically connected to the source/drain features 412P of the pull-up transistor PU1 through the via 506-4 and the source/drain contact 430-6, and is electrically connected to the source/drain features 412P of the pull-up transistor PU2 through the via 506-1 and the source/drain contact 430-1. In some embodiments, the metal conductor 508-2 may be referred to as the (front-side) VDD conductors or the (front-side) VDD lines.

As discussed above, the back-side interconnection structure is under the device region or at the back-side of the device region. The SRAM cell 101A further includes a back-side interconnection structure 602 including metal conductors 604 (including metal conductors 604-1 and 604-2), and an IMD layer 606, which are under (or at the back-side of) the transistors in the SRAM cell 101A (located in the device region, as discussed above) (e.g., the pass-gate transistors PG1 and PG2, the pull-down transistors PD1 and PD2, and the pull-up transistors PU1 and PU2).

The metal conductors 604 are in a (back-side) metal layer BML1 in the IMD layer 606 and extend lengthwise in the Y-direction. The metal layer BML1 is under the SRAM cell 101A, and thus the metal conductors 604 are under the transistors (e.g., the pass-gate transistors PG1 and PG2, the pull-down transistors PD1 and PD2, and the pull-up transistors PU1 and PU2) and the features (including the source/drain contacts 430, the source/drain features 412N/412P, the nanostructures 410, and gate structures 404) of the SRAM cell 101A. Each of the source/drain contacts 432 in the dielectric layer 428 is vertically between and electrically connected to the respective source/drain features 412N/412P and the respective metal conductor 604. The metal conductors 604 may be similar to the metal conductors B_M1 discussed above. The metal conductors 604 and the IMD layer 606 may also be referred to as back-side metal conductors and back-side IMD layer, respectively.

In some embodiments, the metal conductors 604-1 and 604-2 respectively serve as the bit-line and the bit-line-bar that are electrically connected to a controller (e.g., the controller 102 discussed above) and electrically connected to the source/drain features of the pass-gate transistors in the same column of the array of the SRAM cells. As shown in FIGS. 7A to 7H, in the SRAM cell 101A, the metal conductor 604-1 and 604-2 are respectively under the pass-gate transistor PG1 and PG2. The metal conductor 604-1 is electrically connected to the source/drain feature 412N of the pass-gate transistor PG1 through the source/drain contact 432-1, and the metal conductor 604-2 is electrically connected to the source/drain feature 412N of the pass-gate transistor PG2 through the source/drain contact 432-2. In some embodiments, the metal conductors 604-1 and 604-2 may be respectively referred to as (back-side) bit-line conductor and (back-side) bit-line-bar conductor.

The ILD layer 426, the dielectric 428, the ILD layer 514, the IMD layer 516, and the IMD 606 each may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the gate vias 504, the vias 506, the metal conductors 508, the vias 510, the metal conductor 512-1, and the metal conductors 604 are selected from a group consisting of titanium (Ti), titanium nitride (TiN), tantalum (Ta), tantalum nitride (TaN), titanium aluminum nitride (TiAIN), tungsten nitride (WN), tungsten (W), cobalt (Co), molybdenum (Mo), ruthenium (Ru), platinum (Pt), aluminum (Al), copper (Cu), other conductive materials, or a combination thereof.

As shown in FIGS. 7A to 7H, the metal conductors 604-1 and 604-2 (serving as the bit-line and the bit-line-bar) are disposed at the back-side of the SRAM cell 101A, so that the crowded space at the front-side interconnection structure in existing technologies are relieved to reduce the routing complexity of the SRAM cells. Furthermore, the word-line of the SRAM is more concerned about the effect of resistance, such that the metal conductor 512-1 (serving as the word-line) may be designed with wider width, such that the resistance is reduced. As shown in FIGS. 7A to 7H, the metal conductor 512-1 (serving as the word-line) has the widest width in the Y-direction than the other metal conductors 508, 512-1, and 604. Therefore, the RC delay of the SRAM cell 101A are improved, thereby improving the performance of the SRAM cell 101A.

Furthermore, the bit-line and the bit-line-bar of the SRAM are more concerned about the effect of parasitic capacitance. As shown in FIS. 7A to 7H, the source/drain contacts 432 are not surrounded by the gate structures 404 in the Y-direction. This means that there are no parasitic capacitance between the source/drain contacts 432 and the gate structures 404 in the Y-direction. Therefore, the metal conductors 604-1 and 604-3 (which serve as the bit-line and the bit-line-bar) connected to the source/drain contacts 432 also have low parasitic capacitance. Therefore, the RC delay of the SRAM cell 101A are improved, thereby improving the performance of the SRAM cell 101A.

As shown in FIGS. 7A to 7H, the metal conductors 508-1 and 508-3 (serving as the VSS lines) have wider widths in the X-direction and thinner thicknesses than the metal conductors 604-1 and 604-2 (serving as the bit-line and the bit-line-bar). More specifically, each of the metal conductors 508-1 and 508-3 serving as the VSS lines has a width W1 in the Y-direction and a thickness T1, and each of the metal conductors 604-1 and 604-2 serving as the bit-line and the bit-line-bar has a width W2 in the Y-direction and a thickness T2. As shown in FIGS. 7A to 7H, the width W1 of the metal conductors 508-1 and 508-3 in the Y-direction is greater than the width W2 of the metal conductors 604-1 and 604-2 in the Y-direction, and the thickness T1 of the metal conductors 508-1 and 508-3 is less than the thickness T2 of the metal conductors 604-1 and 604-2. In some embodiments, a ratio of the width W1 of the metal conductors 508-1 and 508-3 to the width W2 of the metal conductors 604-1 and 604-2 (i.e., W1/W2) is in a range from about 1.05 to about 3. In some embodiments, a ratio of the thickness T2 of the metal conductors 604-1 and 604-2 to the thickness T1 of the metal conductors 508-1 and 508-3 (i.e., T2/T1) is in a range from about 1.5 to about 10.

The metal conductors 508-1 and 508-3 have wider widths in the X-direction to reduce the resistance and thinner thicknesses to reduce the parasitic capacitance (between the metal conductors 508-1 and 508-3 (serving as the VSS lines) and the metal conductor 512-1 (serving as the word-line). The metal conductors 604-1 and 604-2 have narrower widths in the X-direction to reduce the parasitic capacitance (due to reducing the overlap area between the metal conductors 604-1 and 604-2 and other features of the SRAM cell 101A (e.g., the source/drain features 412N/412P)) and thicker thicknesses to reduce the resistance. Therefore, the RC delay of the SRAM cell 101A are improved, thereby the parasitic capacitance between the metal conductors 508-1 and 508-3 and other features of the SRAM cell 101A is increased improving the performance of the SRAM cell 101A.

If the ratio of the width W1 of the metal conductors 508-1 and 508-3 to the width W2 of the metal conductors 604-1 and 604-2 is too small (i.e., W1/W2 is less than 1.05), then width W1 is too small and/or the width W2 is too large, thereby the resistance of the metal conductors 508-1 and 508-3 is increased and/or the parasitic capacitance between the metal conductors 508-1 and 508-3 and other features of the SRAM cell 101A is increased. If the ratio of the width W1 of the metal conductors 508-1 and 508-3 to the width W2 of the metal conductors 604-1 and 604-2 is too large (i.e., W1/W2 is greater than 3), then width W1 is too large and/or the width W2 is too small, the parasitic capacitance between the metal conductors 508-1 and 508-3 and the metal conductor 512-1 is increased (due to increasing the overlap area between the metal conductors 508-1 and 508-3 and the metal conductor 512-1) and/or the resistance of the metal conductors 604-1 and 604-2 is increased.

If the ratio of the thickness T2 of the metal conductors 604-1 and 604-2 to the thickness T1 of the metal conductors 508-1 and 508-3 is too small (i.e., T2/T1 is less than 1.5), then the thickness T2 is too small and/or the thickness T1 is too large, thereby the resistance of the metal conductors 604-1 and 604-2 is increased and/or the parasitic capacitance between the metal conductors 508-1 and 508-3 and the metal conductor 512-1 is increased (due to being more close to the metal conductor 512-1). If the ratio of the thickness T2 of the metal conductors 604-1 and 604-2 to the thickness T1 of the metal conductors 508-1 and 508-3 is too large (i.e., T2/T1 is greater than 10), then the thickness T2 is too large and/or the thickness T1 is too small, the process window of the metal conductors 604-1 and 604-2 is reduced and/or the resistance of metal conductors 508-1 and 508-3 is increased.

As discussed above, referring back to FIG. 2, the metal conductors disposed under the SRAM cells may also be routed to the front-side conductors over the SRAM cells through the tap structures 2000 located in the edge strap regions and the edge cell regions. The metal conductors 604-1 and 604-2 in the SRAM cell 101A (serving as the bit-line and the bit-line-bar) may extend in the Y-direction to the edge strap regions of the array constructed by the SRAM cells 101A, and then may be routed to the front-side conductors through the tap structures (e.g., the tap structures 2000).

FIG. 8 illustrates a cross sectional view of tap structures 2000 in FIG. 2 for connecting the metal conductor 604-1 or 604-2 at the back-side to a front-side metal conductor at the front-side, in accordance with some embodiments of the present disclosure. As shown in FIG. 8, a tap structure 2000 may electrically connect the metal conductor 604-1 or 604-2 to a front-side bit-line conductor 2012 electrically connected to the controller (e.g., the controller 102). The tap structure 2000 may include a via 2004, a tap via 2006, a contact feature 2008, a via 2010. The via 2004 is at the back-side of the device region discussed above, and the via 2010 and the contact feature 2008 are at the front-side of the device region. In some embodiments, the via 2004 and the source/drain contacts 432 are formed at the same fabrication operation, the contact feature 2008 and the source/drain contacts 430 are formed at the same fabrication operation, and the via 2010 and the via 506 are formed at the same fabrication operation. In some embodiments, the tap via 2006 is formed after the formation of the gate vias 504. Such tap structure 2000 for the metal conductor 604-1 or 604-2 served as bit-line or bit-line-bar may be referred to as bit-line tap structure or bit-line-bar tap structure. It should be noted that the tap structure 2000 may be applied for connecting any back-side metal conductor to a front-side metal conductor. It should be noted that the tap structure 2000 may have more vias and more metal conductors.

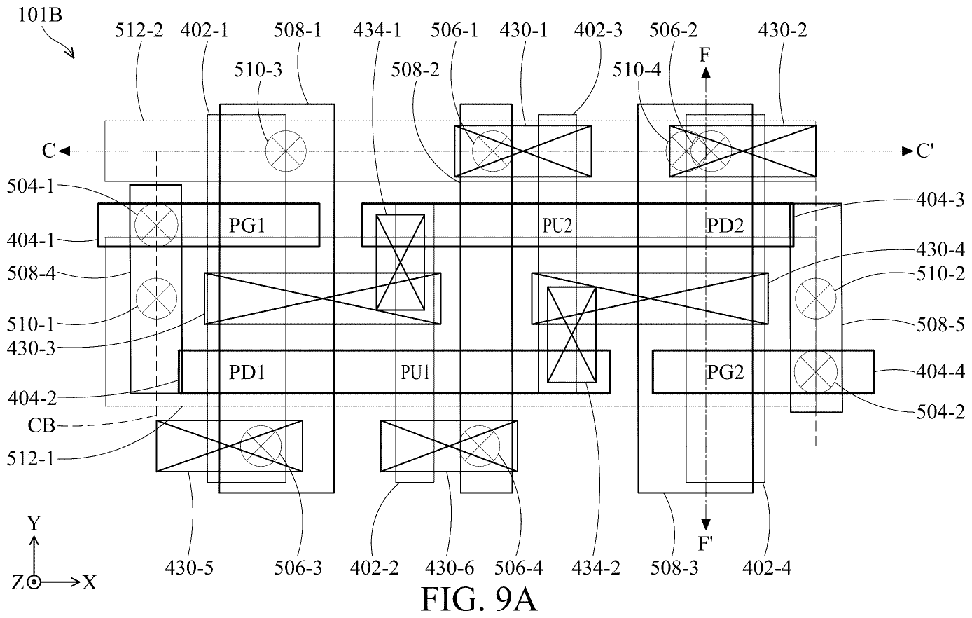

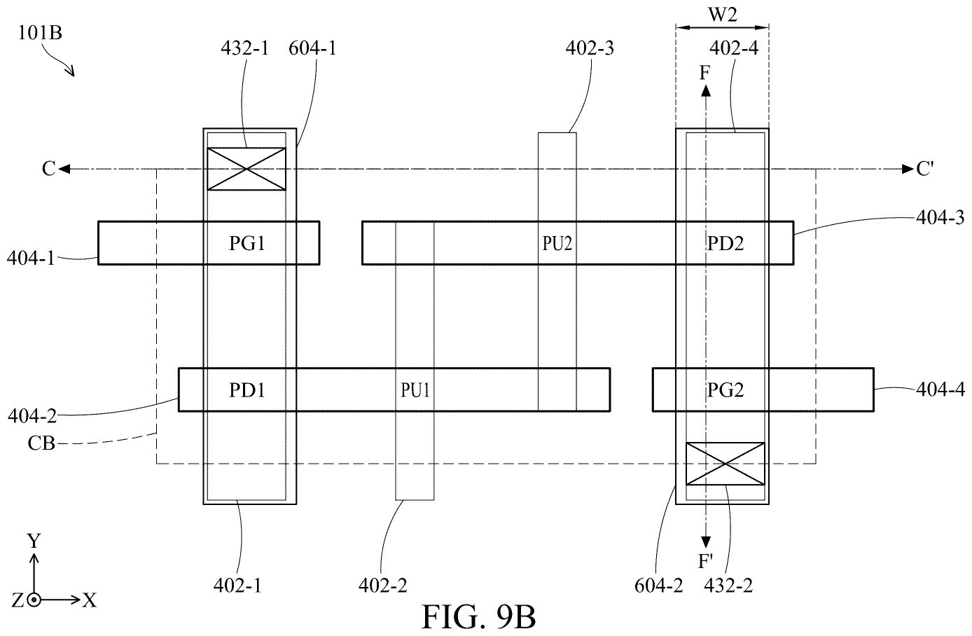

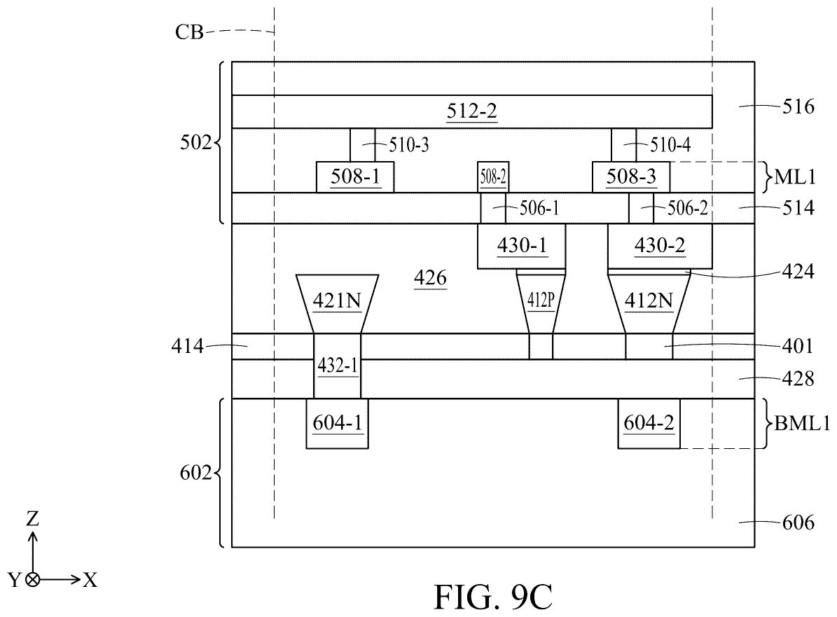

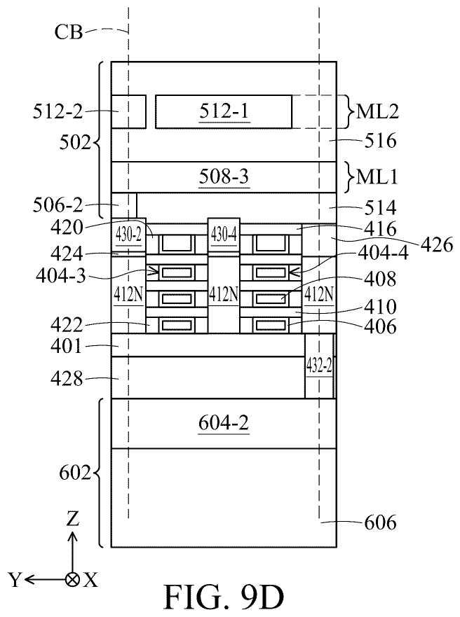

FIGS. 9A and 9B illustrate top views (or layouts) of an SRAM cell 101B in a semiconductor device, in accordance with some alternative embodiments of the present disclosure, in which FIG. 9A illustrates the features in a device region and a front-side interconnection structure, and FIG. 9B illustrates the features in the device region and a back-side interconnection structure.

FIG. 9C illustrates an X-Z cross-sectional view of the SRAM cell 101B in the semiconductor device along a line C-C′ in FIGS. 9A and 9B, in accordance with some alternative embodiments of the present disclosure. FIG. 9D illustrates a Y-Z cross-sectional view of the SRAM cell 101B in the semiconductor device along a line F-F′ in FIGS. 9A and 9B, in accordance with some alternative embodiments of the present disclosure.

The SRAM cell 101B is similar to the SRAM cell 101A discussed above, except that the SRAM cell 101B further includes vias 510-3 and 510-4 and a metal conductor 512-2, which are over (or at the front-side of) the transistors in the SRAM cell 101B (located in the device region, as discussed above) (e.g., the pass-gate transistors PG1 and PG2, the pull-down transistors PD1 and PD2, and the pull-up transistors PU1 and PU2). More specifically, as shown in FIGS. 9A to 9D, the front-side interconnection structure 502 further includes the vias 510-3 and 510-4 and the metal conductor 512-2. The metal conductor 512-2 is in the (front-side) metal layer ML2 in the IMD layer 516 and extends lengthwise in the X-direction, and the vias 510-3 and 510-4 are in the IMD layer 516. Each of the vias 510-3 and 510-4 is vertically between and electrically connected to the respective metal conductor 508 and the respective metal conductor 512-2.

Furthermore, as shown in FIG. 9A, the metal conductor 512-2 lengthwise overlaps the cell boundary CB in the top view, and the vias 510-3 and 510-4 overlap the cell boundary CB in the top view. The vias 510-3 and 510-4 and the metal conductor 512-2 may be respectively similar the vias V1, and the metal conductors M2 discussed above. The vias 510-3 and 510-4 and the metal conductor 512-2 may also be referred to as front-side vias and front-side metal conductors, respectively.

As discussed above, the metal conductors 508-1 and 508-3 are electrically coupled to the voltage node (or voltage source) VSS. The metal conductor 510-2 is electrically connected to the metal conductors 508-1 and 508-3 to serve as a power mesh line for connecting the voltage node VSS to the metal conductors 508-1 and 508-3. As shown in FIGS. 9A to 9D, in the SRAM cell 101A, the metal conductor 510-1 is electrically connected to the metal conductor 508-1 through the via 510-3 and electrically connected to the metal conductor 508-3 through the via 510-4. In some embodiments, the metal conductor 510-2 may be referred to as a (front-side) VSS power mesh line or a VSS power mesh conductor.

In some embodiments, the metal conductors 508-1, 508-3, and 512-2 may also be seen to be electrically connected with each other in parallel, such that the total resistance of the metal conductors 508-1, 508-3, and 512-2 are reduced, thereby improving the performance of the SRAM cell 101B.

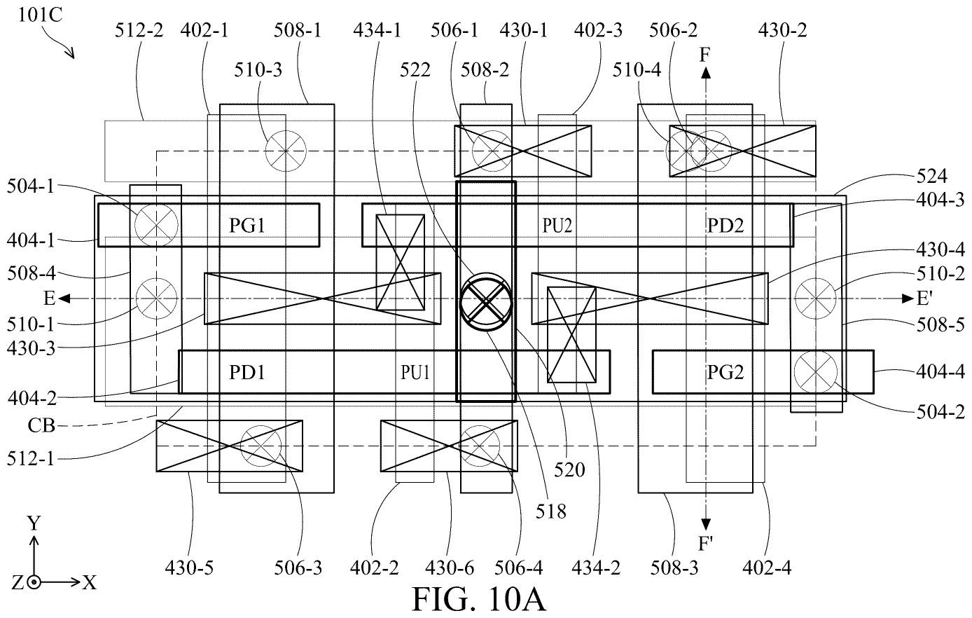

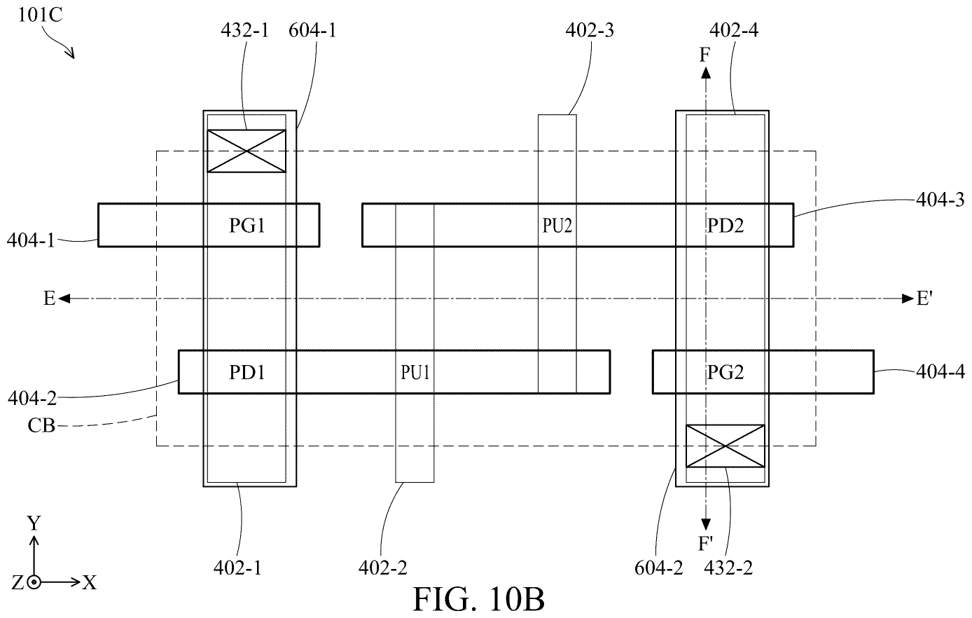

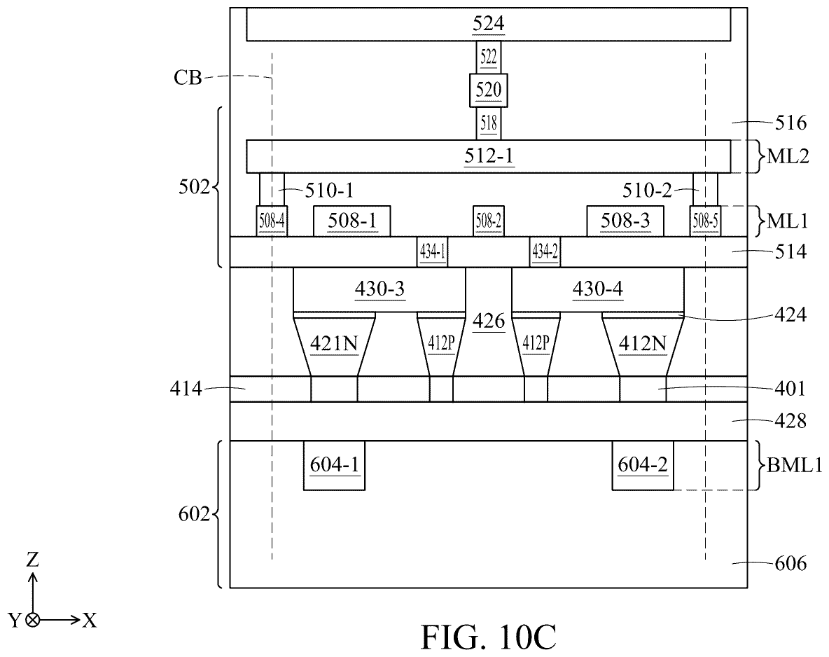

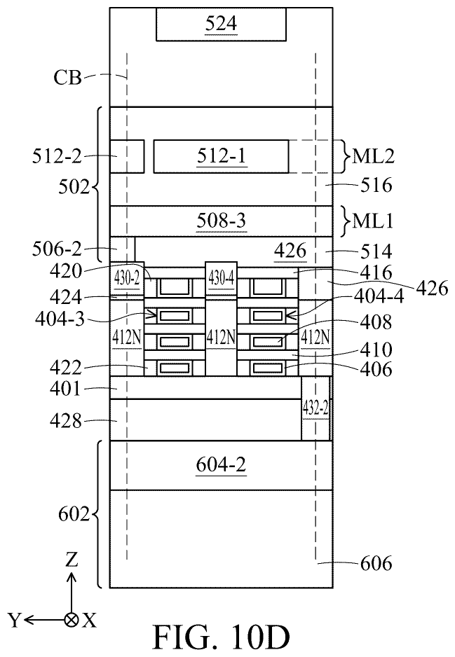

FIGS. 10A and 10B illustrate top views (or layouts) of an SRAM cell 101C in a semiconductor device, in accordance with some alternative embodiments of the present disclosure, in which FIG. 10A illustrates the features in a device region and a front-side interconnection structure, and FIG. 10B illustrates the features in the device region and a back-side interconnection structure.

FIG. 10C illustrates an X-Z cross-sectional view of the SRAM cell 101C in the semiconductor device along a line E-E′ in FIGS. 10A and 10B, in accordance with some alternative embodiments of the present disclosure. FIG. 10D illustrates a Y-Z cross-sectional view of the SRAM cell 101C in the semiconductor device along a line F-F′ in FIGS. 10A and 10B, in accordance with some alternative embodiments of the present disclosure.

The SRAM cell 101C is similar to the SRAM cell 101B discussed above, except that the SRAM cell 101C further includes a via 518, a metal conductor 520, a via 522, and a metal conductor 524, which are over (or at the front-side of) the transistors in the SRAM cell 101C (located in the device region, as discussed above) (e.g., the pass-gate transistors PG1 and PG2, the pull-down transistors PD1 and PD2, and the pull-up transistors PU1 and PU2). More specifically, as shown in FIGS. 10A to 10D, the front-side interconnection structure 502 further includes the via 518, the metal conductor 520, the via 522, and the metal conductor 524. The metal conductor 520 is in a (front-side) metal layer ML3 in the IMD layer 516 and extend lengthwise in the Y-direction, and the metal conductor 524 is in a (front-side) metal layer ML4 in the IMD layer 516 and extends lengthwise in the X-direction. The metal layer ML3 is over the metal layer ML2 and the metal layer ML4 is over the metal layer ML3, and thus the metal conductor 520 is over the metal conductors 512-1 and 512-2 and the metal conductor 524 is over the metal conductor 520.

The via 518 and 522 are in the IMD layer 516. The via 518 is vertically between and electrically connected to the metal conductor 512-1 and the metal conductor 520. The via 522 is vertically between and electrically connected to the metal conductor 520 and the metal conductor 524. The vias 518, the metal conductor 520, the via 522, and the metal conductor 524 may be respectively similar the vias V2, the metal conductors M3, the vias V3, and the metal conductors M4 discussed above. The vias 518 and 522 and the metal conductors 520 and 524 may also be referred to as front-side vias and front-side metal conductors, respectively.

In some embodiments, the metal conductor 524 serves as the word-line that is electrically connected to the metal conductor 512-1 (serving as the word-line) for a double world-line connection. The metal conductor 524 is electrically connected to the metal conductor 512-1 through the via 522, the metal conductor 520, and the via 518. In some embodiments, the metal conductor 524 may be referred to as (front-side) word-line conductor. In some embodiments, the metal conductors 524 and 512-1 may also be seen to be electrically connected with each other in parallel, such that the total resistance of the metal conductors 524 and 512-1 are reduced, thereby improving the performance of the SRAM cell 101B.

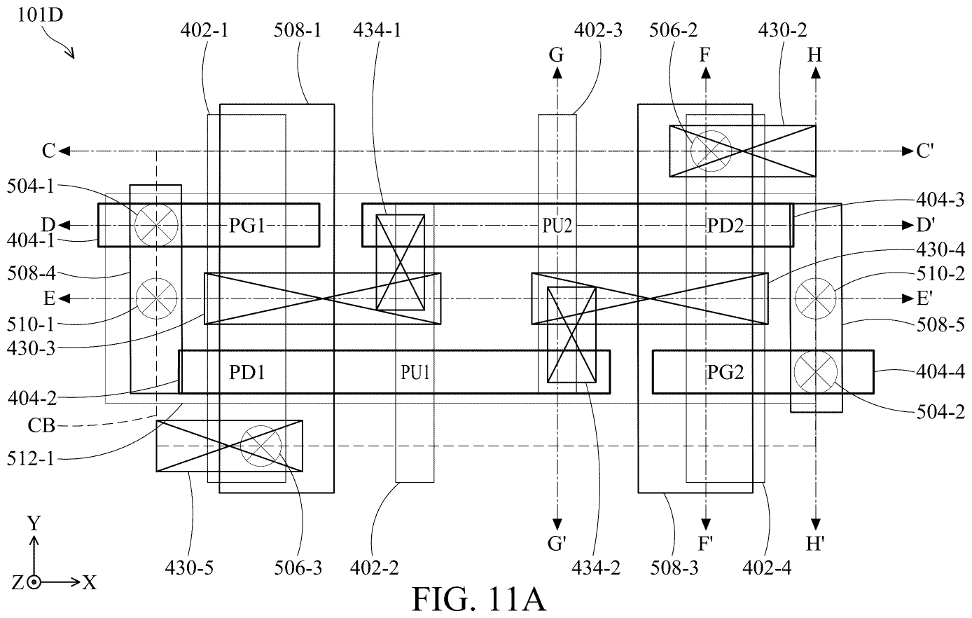

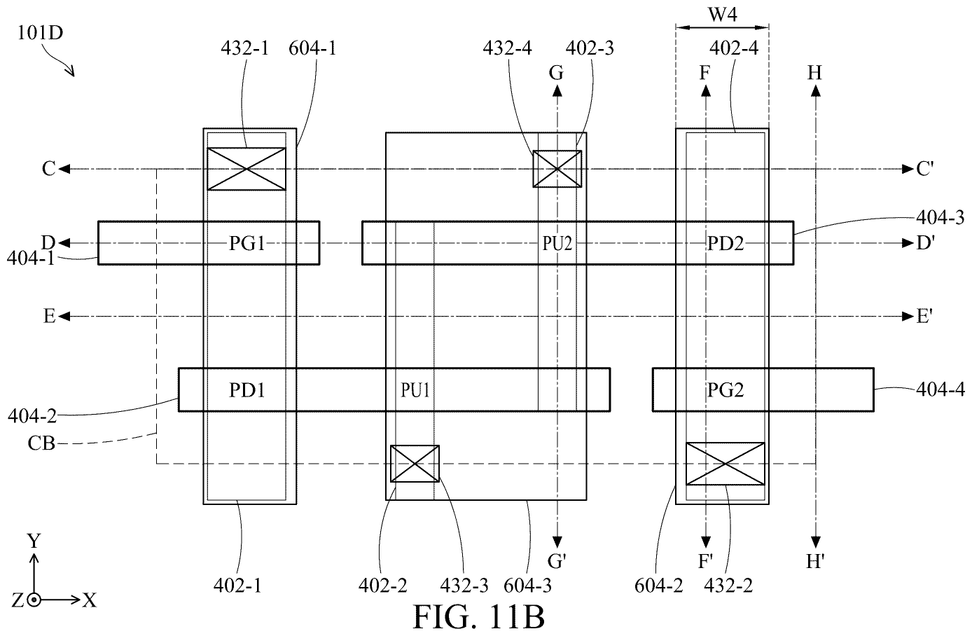

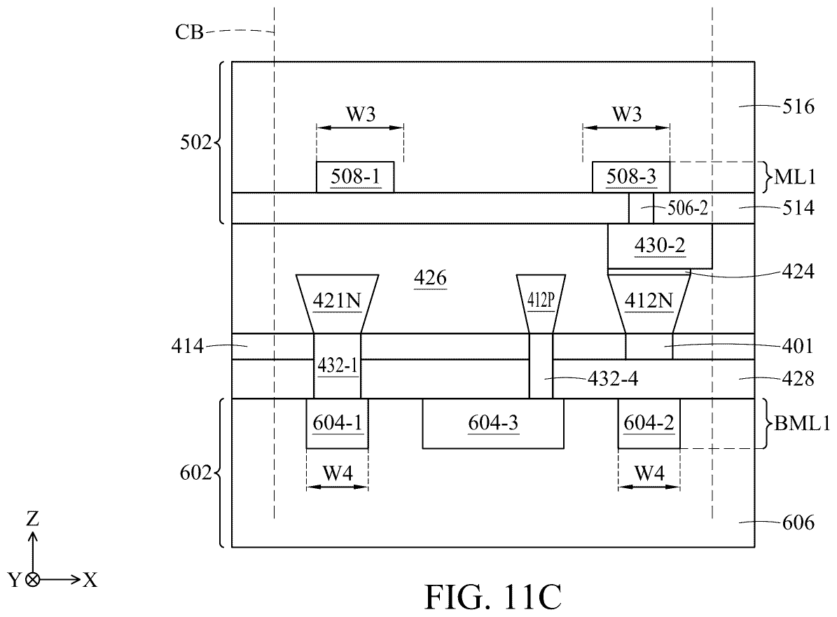

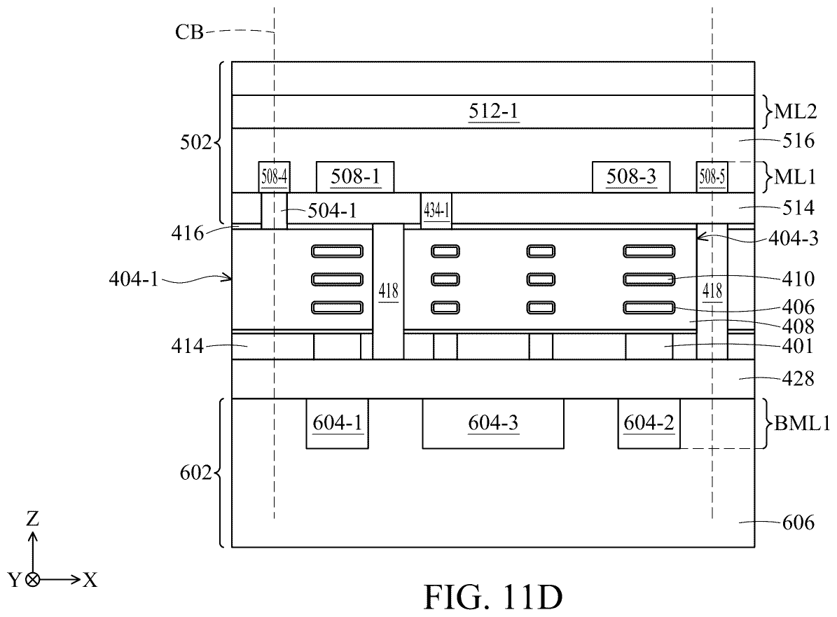

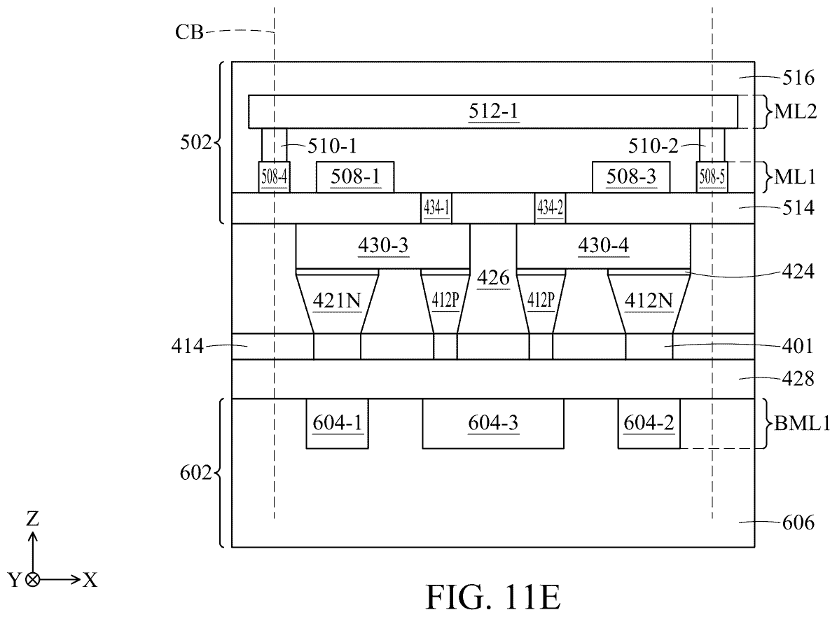

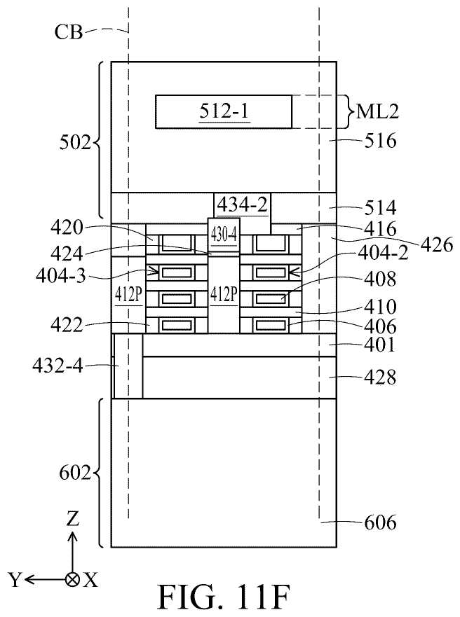

FIGS. 11A and 11B illustrate top views (or layouts) of an SRAM cell 101D in a semiconductor device, in accordance with some alternative embodiments of the present disclosure, in which FIG. 11A illustrates the features in a device region and a front-side interconnection structure, and FIG. 11B illustrates the features in the device region and a back-side interconnection structure.

FIG. 11C illustrates an X-Z cross-sectional view of the SRAM cell 101D in the semiconductor device along a line C-C′ in FIGS. 11A and 11B, in accordance with some alternative embodiments of the present disclosure. FIG. 11D illustrates an X-Z cross-sectional view of the SRAM cell 101D in the semiconductor device along a line D-D′ in FIGS. 11A and 11B, in accordance with some alternative embodiments of the present disclosure. FIG. 11E illustrates an X-Z cross-sectional view of the SRAM cell 101D in the semiconductor device along a line E-E′ in FIGS. 11A and 11B, in accordance with some alternative embodiments of the present disclosure. FIG. 11F illustrates a Y-Z cross-sectional view of the SRAM cell 101D in the semiconductor device along a line G-G′ in FIGS. 11A and 11B, in accordance with some alternative embodiments of the present disclosure.

The SRAM cell 101D is similar to the SRAM cell 101A discussed above, except that the SRAM cell 101D further includes source/drain contacts 432-3 and 432-4, and a metal conductor 604-3, which are under (or at the back-side of) the transistors in the SRAM cell 101D (located in the device region, as discussed above) (e.g., the pass-gate transistors PG1 and PG2, the pull-down transistors PD1 and PD2, and the pull-up transistors PU1 and PU2). Furthermore, the source/drain contacts 430-1 and 430-6, the vias 506-1 and 506-4, and the metal conductor 508-2 of the SRAM cell 101A discussed above are omitted.

The source/drain contacts 432-3 and 432-4 are disposed in the dielectric layer 428. In the top view, as shown in FIGS. 11A and 11B, the source/drain contacts 432-3 and 432-4 lengthwise overlap the cell boundary CB. In the top view, as shown in FIGS. 11A and 11B, the source/drain contact 432-3 is adjacent to the gate structure 404-2 (or is adjacent to the pull-up transistor PU1) in the Y-direction; and the source/drain contact 432-4 is adjacent to the gate structure 404-3 (or is adjacent to the pull-up transistor PU2) in the Y-direction. Furthermore, each of the source/drain contacts 432-3 and 432-4 is under electrically connected to the respective source/drain features 412N/412P. Specifically, as shown in FIGS. 11A to 11F, the source/drain contact 432-3 is under and electrically connected to the source/drain feature 412P of the pull-up transistor PU1; and the source/drain contact 432-4 is under and electrically connected to the source/drain feature 412P of the pull-up transistor PU2. In some embodiments, the source/drain contacts 432-3 and 432-4 may be referred to as back-side source/drain contacts due to the source/drain contacts 432-3 and 432-4 being disposed under the source/drain features 412P.

The metal conductor 604-3 are in the (back-side) metal layer BML1 in the IMD layer 606 and extend lengthwise in the Y-direction. The metal layer BML1 is under the SRAM cell 101D, and thus the metal conductor 604-3 is under the transistors (e.g., the pass-gate transistors PG1 and PG2, the pull-down transistors PD1 and PD2, and the pull-up transistors PU1 and PU2) and the features (including the source/drain contacts 430, the source/drain features 412N/412P, the nanostructures 410, and gate structures 404) of the SRAM cell 101D. As shown in FIGS. 11B to 11E, the metal conductor 604-3 is also between the metal conductors 604-1 and 604-2 in the X-direction. In some embodiments, the metal conductor 604-3 overlaps the active areas 402-2 and 402-3, as shown in FIG. 11B. Each of the source/drain contacts 432-3 and 432-4 in the dielectric layer 428 is vertically between and electrically connected to the respective source/drain features 412P and the metal conductor 604-3. The metal conductor 604-3 may be similar to the metal conductors B_M1 discussed above. The metal conductor 604-3 may also be referred to as back-side metal conductor.

In some embodiments, the metal conductor 604-3 also serves as the VDD line that is electrically coupled to a voltage node or voltage source (not shown) (e.g., the voltage node (or voltage source) VDD discussed above) and electrically connected to the source/drain features of the pull-up transistors in the same column of the array of the SRAM cell. As shown in FIGS. 11A to 11F, in the SRAM cell 101D, the metal conductor 604-3 is under the pull-up transistors PU1 and PU2. The metal conductor 604-3 is electrically connected to the source/drain feature 412P of the pull-up transistor PU1 through the source/drain contact 432-3, and is electrically connected to the source/drain feature 412P of the pull-up transistor PU2 through the source/drain contact 432-4. In some embodiments, the metal conductor 604-3 may also be referred to as (back-side) VDD conductor or (back-side) VDD line.

Due to the metal conductor serving as the VDD line (e.g., the metal conductor 604-3) being designed in the (back-side) metal layer BML1, the metal conductors 508-1 and 508-3 (serving as the VSS lines) shown in FIGS. 11A to 11F can be designed to have wider widths in the X-direction than that shown in FIGS. 7A to 7G. More specifically, each of the metal conductors 508-1 and 508-3 (serving as the VSS lines) shown in FIGS. 11A to 11F has a width W3 in the Y-direction, and each of the metal conductors 604-1 and 604-2 (serving as the bit-line and the bit-line-bar) shown in FIGS. 11A to 11F has a width W4 in the Y-direction. As shown in FIGS. 11A to 11F, the width W3 of the metal conductors 508-1 and 508-3 in the Y-direction is greater than the width W4 of the metal conductors 604-1 and 604-2 in the Y-direction. In some embodiments, a ratio of the width W3 of the metal conductors 508-1 and 508-3 to the width W4 of the metal conductors 604-1 and 604-2 (i.e., W1/W2) is in a range from about 1.2 to about 3.

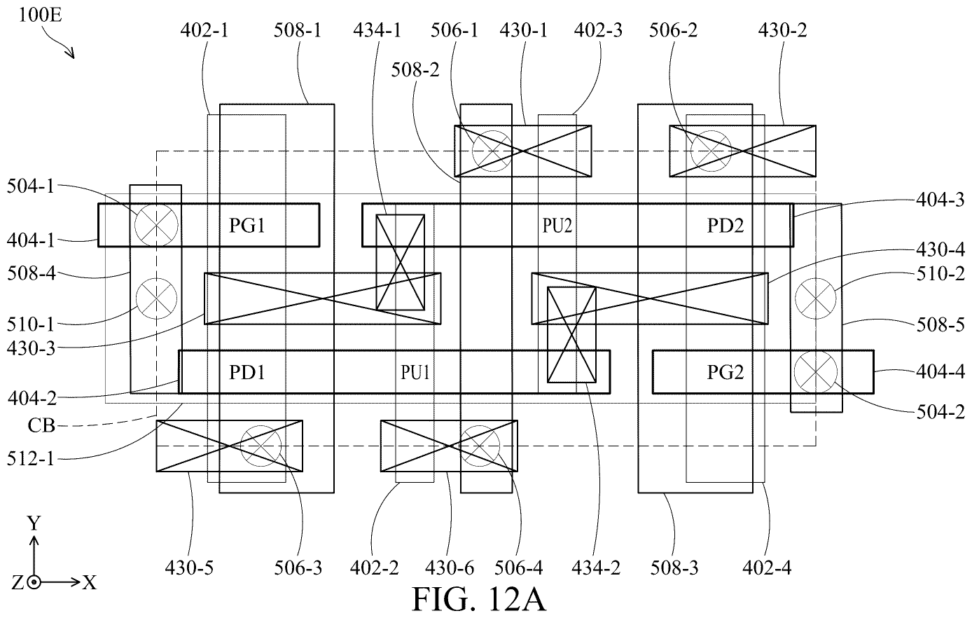

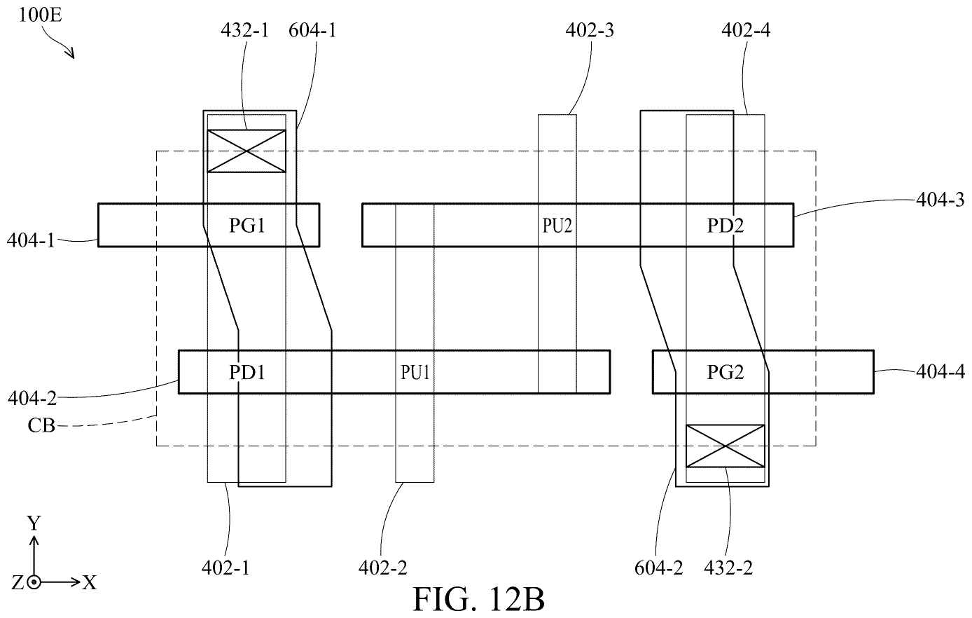

FIGS. 12A and 12B illustrate top views (or layouts) of an SRAM cell 101E in a semiconductor device, in accordance with some alternative embodiments of the present disclosure, in which FIG. 12A illustrates the features in a device region and a front-side interconnection structure, and FIG. 12B illustrates the features in the device region and a back-side interconnection structure.

The SRAM cell 101E is similar to the SRAM cell 101A discussed above, except that the metal conductors serving as the bit-line and the bit-line-bar are asymmetric shapes. As shown in FIGS. 12A and 12B, the metal conductors 604-1 and 604-2 serving as the bit-line and the bit-line-bar are asymmetric shapes in the top view. More specifically, each of the metal conductors 604-1 and 604-2 has a bend portion, such that the metal conductors 604-1 and 604-2 become the asymmetric shapes in the top view, as show in FIGS. 12A and 12B. In some embodiments, the metal conductors 604-1 and 604-2 are bent shapes in the top view.

Referring back to FIG. 7B, each of the metal conductors 604-1 and 604-2 is close to cell boundary CB in the X-direction (specifically, the cell short boundaries of the cell boundary CB in the Y-direction). This also means that the metal conductors 604-1 and 604-2 of the SRAM cell 101A shown in FIGS. 7A to 7H are also close to other features of the other device adjacent to the SRAM cell 101A in the X-direction (e.g., the metal conductors of the SRAM similar to the metal conductors 604-1 and 604-2). As shown in FIGS. 12A and 12B, due to the metal conductors 604-1 and 604-2 serving as the bit-line and the bit-line-bar are asymmetric shapes or bent shapes in the top view, portions of the metal conductors 604-1 and 604-2 are further away from the cell boundary CB in the X-direction, thereby being further away from the other features of the other device adjacent to the SRAM cell 101E in the X-direction. Therefore, the parasitic capacitance and the interference from the other device adjacent to the SRAM cell 101E to the metal conductors 604-1 and 604-2 are reduced, thereby improving the performance of the SRAM cell 101E.

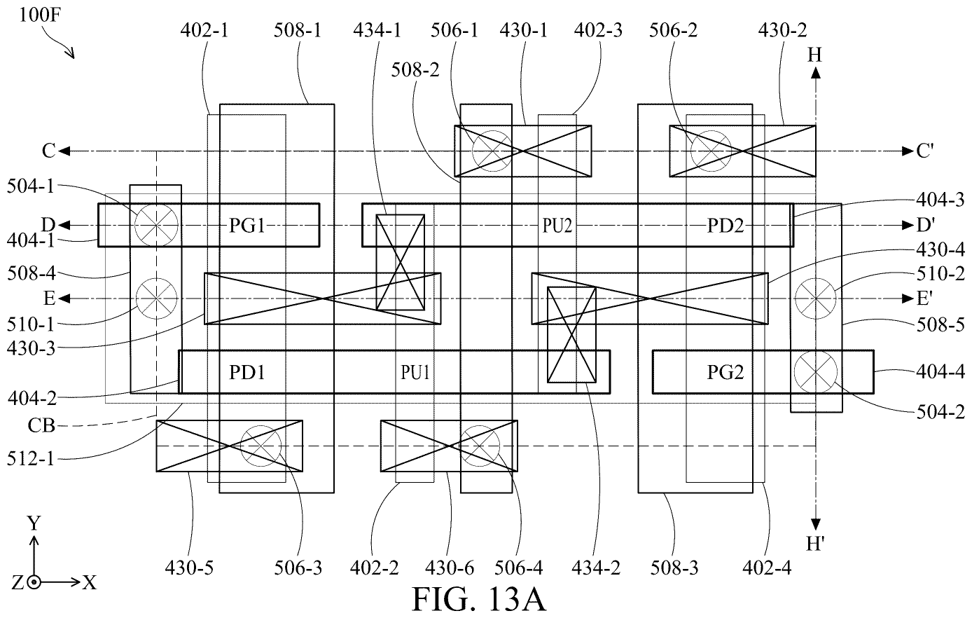

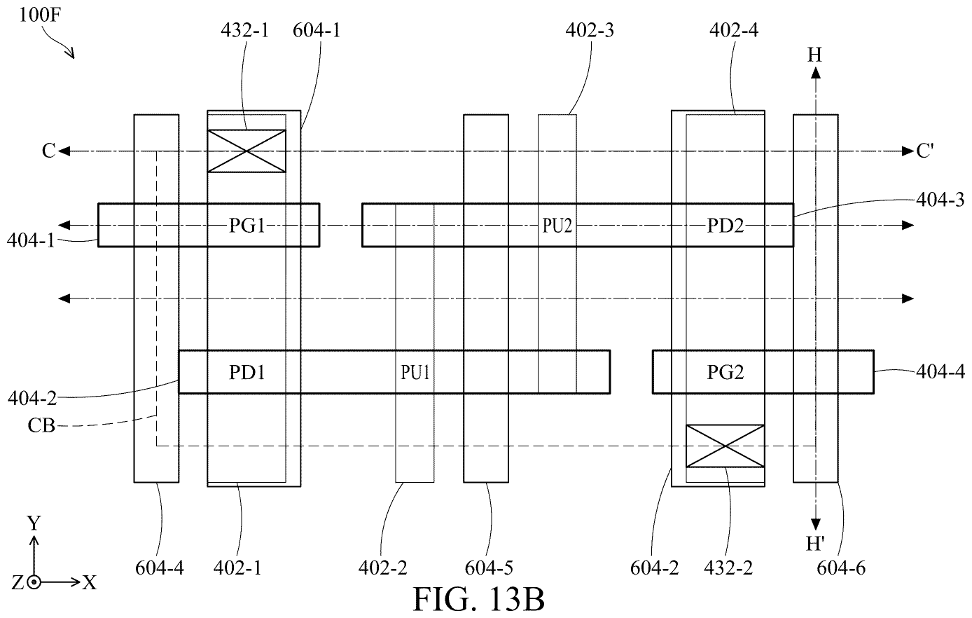

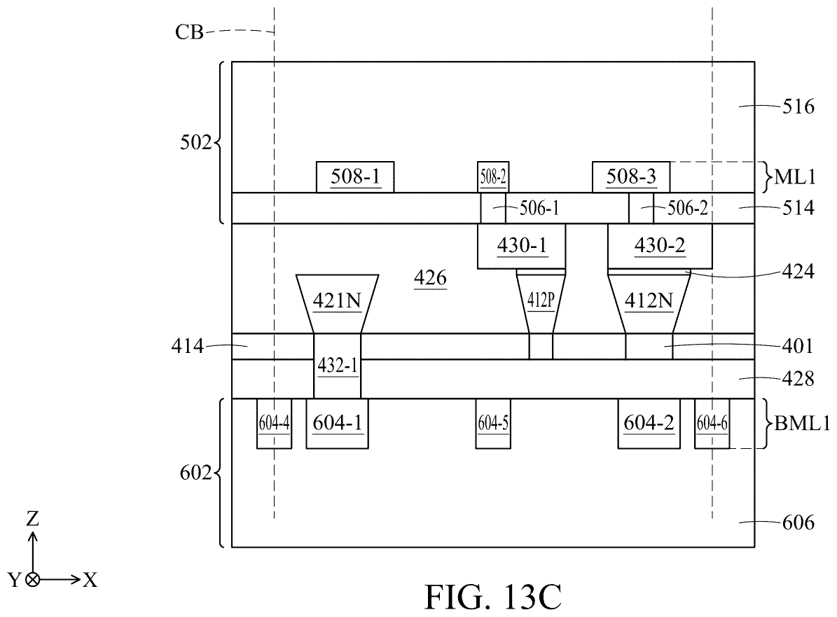

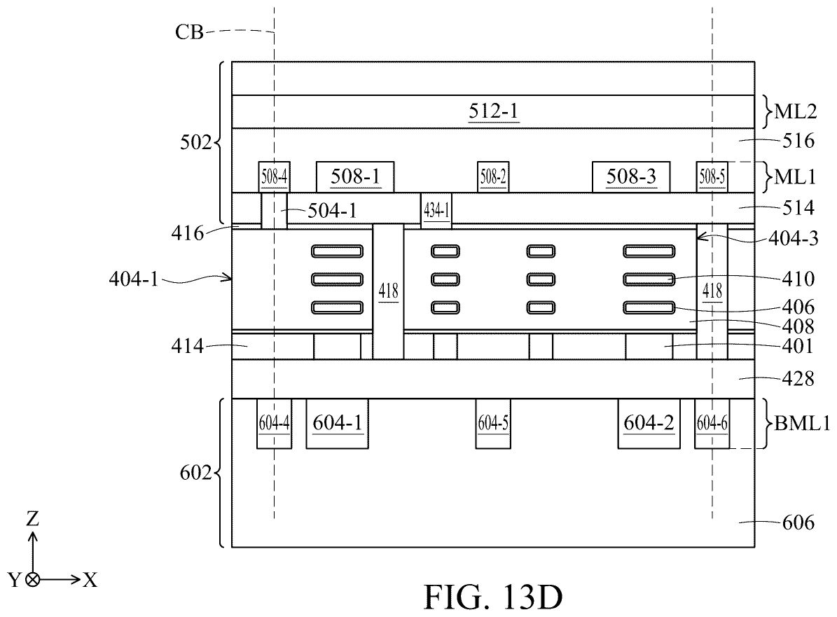

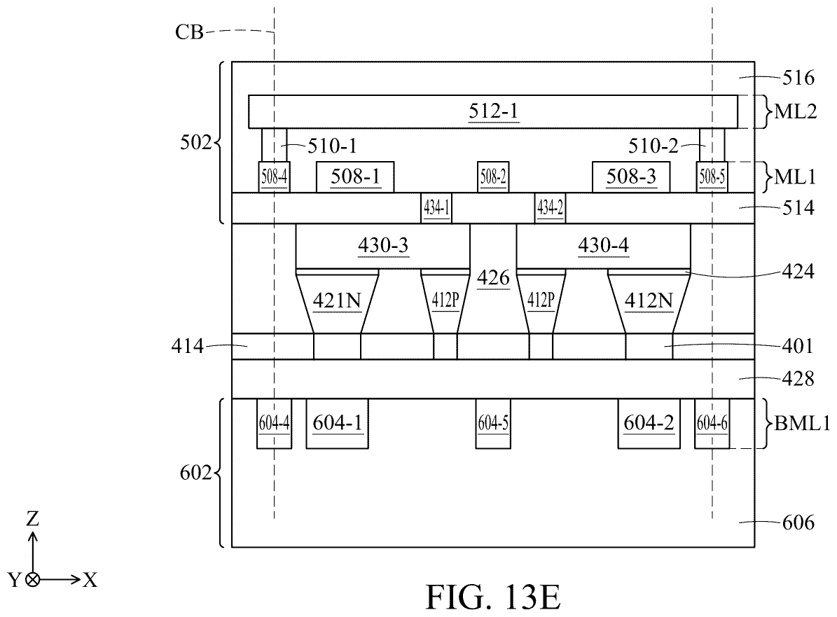

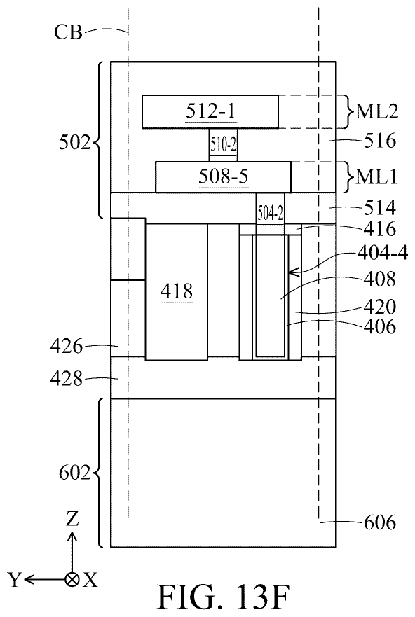

FIGS. 13A and 13B illustrate top views (or layouts) of an SRAM cell 100F in a semiconductor device, in accordance with some alternative embodiments of the present disclosure, in which FIG. 13A illustrates the features in a device region and a front-side interconnection structure, and FIG. 13B illustrates the features in the device region and a back-side interconnection structure.

FIG. 13C illustrates an X-Z cross-sectional view of the SRAM cell 100F in the semiconductor device along a line C-C′ in FIGS. 13A and 13B, in accordance with some alternative embodiments of the present disclosure. FIG. 13D illustrates an X-Z cross-sectional view of the SRAM cell 100F in the semiconductor device along a line D-D′ in FIGS. 13A and 13B, in accordance with some alternative embodiments of the present disclosure. FIG. 13E illustrates an X-Z cross-sectional view of the SRAM cell 100F in the semiconductor device along a line E-E′ in FIGS. 13A and 13B, in accordance with some alternative embodiments of the present disclosure. FIG. 13F illustrates a Y-Z cross-sectional view of the SRAM cell 100F in the semiconductor device along a line H-H′ in FIGS. 13A and 13B, in accordance with some alternative embodiments of the present disclosure.

The SRAM cell 101F is similar to the SRAM cell 101A discussed above, except that the SRAM cell 101F further includes metal conductors 604-4, 604-5, and 604-6, which are under (or at the front-side of) the transistors in the SRAM cell 101F (located in the device region, as discussed above) (e.g., the pass-gate transistors PG1 and PG2, the pull-down transistors PD1 and PD2, and the pull-up transistors PU1 and PU2). More specifically, as shown in FIGS. 9A to 9D, the back-side interconnection structure 602 further includes the metal conductors 604-4, 604-5, and 604-6. The metal conductors 604-4, 604-5, and 604-6 is in the (back-side) metal layer BML1 in the IMD layer 606 and extend lengthwise in the Y-direction. The metal layer BML1 is under the SRAM cell 101F, and thus the metal conductors 604-4, 604-5, and 604-6 are under the transistors (e.g., the pass-gate transistors PG1 and PG2, the pull-down transistors PD1 and PD2, and the pull-up transistors PU1 and PU2) and the features (including the source/drain contacts 430, the source/drain features 412N/412P, the nanostructures 410, and gate structures 404) of the SRAM cell 101F.

As shown in FIGS. 13A to 13F, the metal conductor 604-5 is also between the metal conductors 604-1 and 604-2 in the X-direction. Furthermore, as shown in FIGS. 13A to 13F, the metal conductors 604-4 and 604-6 lengthwise overlap the cell boundary CB in the top view. In some aspects, the metal conductors 604-4 and 604-6 are disposed on opposite sides of the metal conductors 604-1, 604-5, and 604-2 in the X-direction, as shown in FIGS. 13A to 13F. The metal conductors 604-4, 604-5, and 604-6 may be respectively similar the metal conductors B_M1 discussed above. The metal conductors 604-4, 604-5, and 604-6 may also be referred to as back-side metal conductors, respectively.

The metal conductors 604-4, 604-5, and 604-6 are floating of electrically coupled to a voltage node or voltage source (not shown) (e.g., the voltage node (or voltage source) VDD or VSS discussed above). In some embodiments, the metal conductors 604-4, 604-5, and 604-6 may be referred to as the (back-side) VDD/VSS conductors or the (back-side) VDD/VSS lines (but not used for proving power to the SRAM 101F). As shown in FIGS. 13A to 13F, the metal conductors 604-4, 604-5, and 604-6 are electrically isolated from the features of the features (including the source/drain contacts 430, the source/drain features 412N/412P, the nanostructures 410, and gate structures 404) of the SRAM cell 101F. The metal conductors 604-4, 604-5, and 604-6 are used for enhancing the isolation of the metal conductors 604-1 and 604-2 to reduce the interference from the other device adjacent to the SRAM cell 101F to the metal conductors 604-1 and 604-2, thereby improving the performance of the SRAM cell 101F. In some embodiments, the metal conductors 604-4, 604-5, and 604-6 may also be referred to as (back-side) dummy metal conductors.

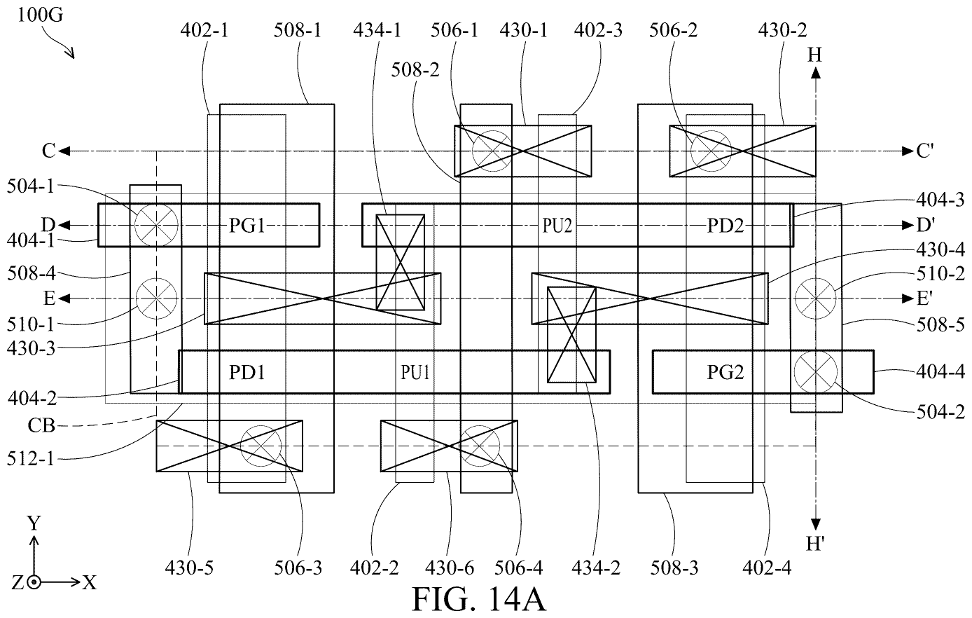

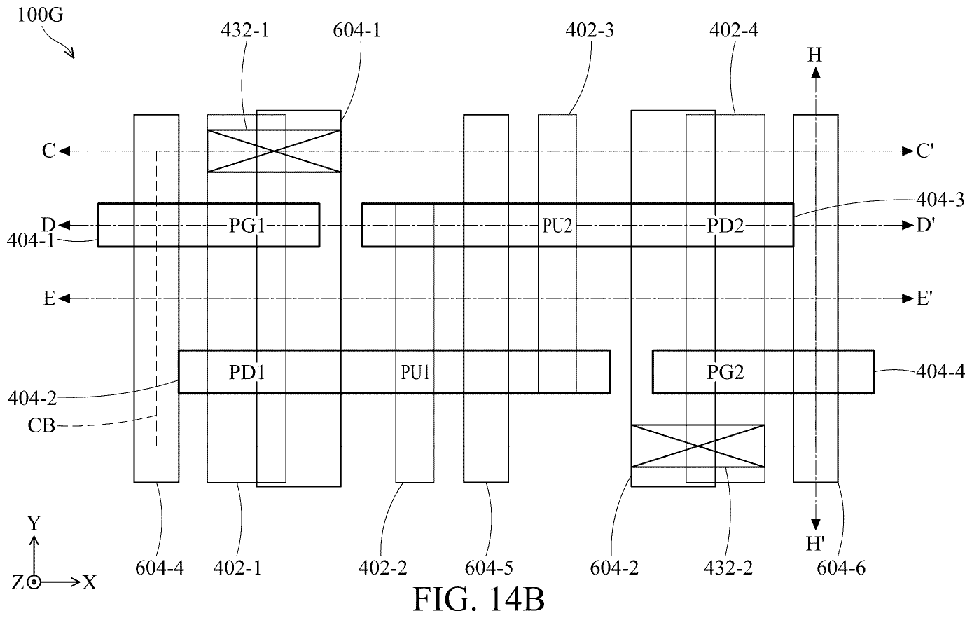

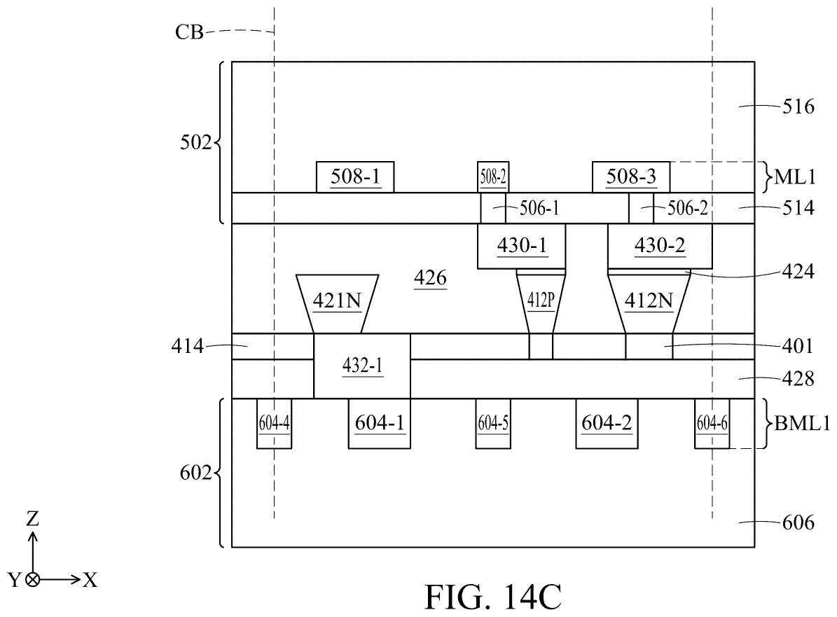

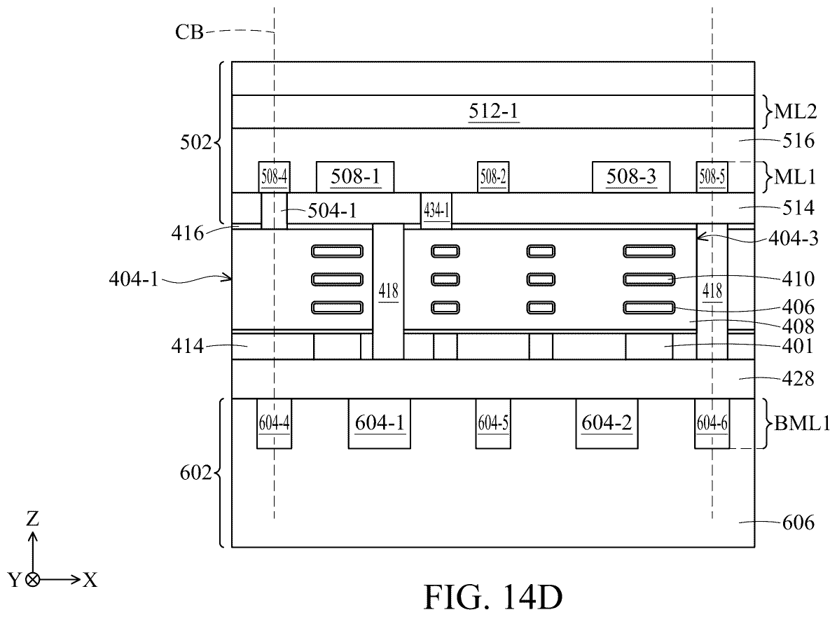

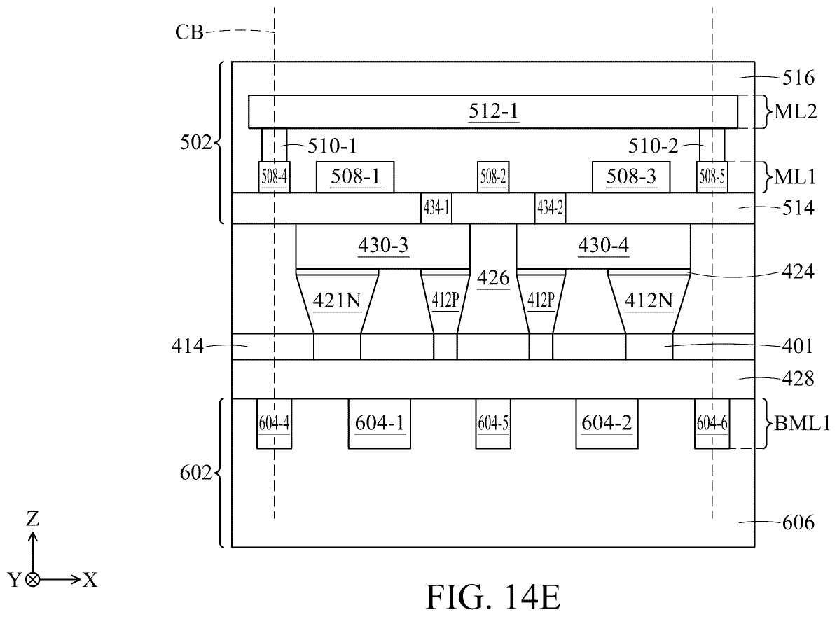

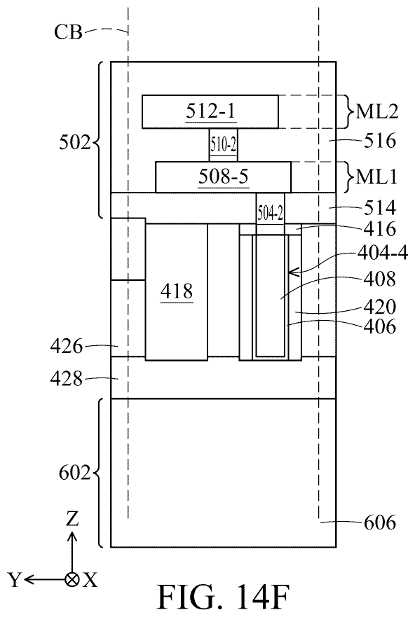

FIGS. 14A and 14B illustrate top views (or layouts) of an SRAM cell 100G in a semiconductor device, in accordance with some alternative embodiments of the present disclosure, in which FIG. 14A illustrates the features in a device region and a front-side interconnection structure, and FIG. 14B illustrates the features in the device region and a back-side interconnection structure.

FIG. 14C illustrates an X-Z cross-sectional view of the SRAM cell 100G in the semiconductor device along a line C-C′ in FIGS. 14A and 14B, in accordance with some alternative embodiments of the present disclosure. FIG. 14D illustrates an X-Z cross-sectional view of the SRAM cell 100G in the semiconductor device along a line D-D′ in FIGS. 14A and 14B, in accordance with some alternative embodiments of the present disclosure. FIG. 14E illustrates an X-Z cross-sectional view of the SRAM cell 100G in the semiconductor device along a line E-E′ in FIGS. 14A and 14B, in accordance with some alternative embodiments of the present disclosure. FIG. 14F illustrates a Y-Z cross-sectional view of the SRAM cell 100G in the semiconductor device along a line H-H′ in FIGS. 14A and 14B, in accordance with some alternative embodiments of the present disclosure.

The SRAM cell 101G is similar to the SRAM cell 101F discussed above, except that the metal conductors 604-1 and 604-2 serving as the bit-line and the bit-line-bar are further away from the cell boundary CB in the X-direction. Referring back to FIG. 13B, the metal conductors 604-1 and 604-2 shown in FIG. 13B fully overlap the active areas 402-1 and 402-4 in the top view. As shown in FIG. 14B, due to the metal conductors 604-1 and 604-2 being further away from the cell boundary CB in the X-direction, the metal conductors 604-1 and 604-2 partially overlap the active areas 402-1 and 402-4 in the top view.

Similar to the above discussion, the metal conductors 604-1 and 604-2 serving as the bit-line and the bit-line-bar are further away from the metal conductors 604-4 and 604-6 in the X-direction, thereby the parasitic capacitance and the interference from the metal conductors 604-4 and 604-6 to the metal conductors 604-1 and 604-2 are reduced, thereby improving the performance of the SRAM cell 101E.

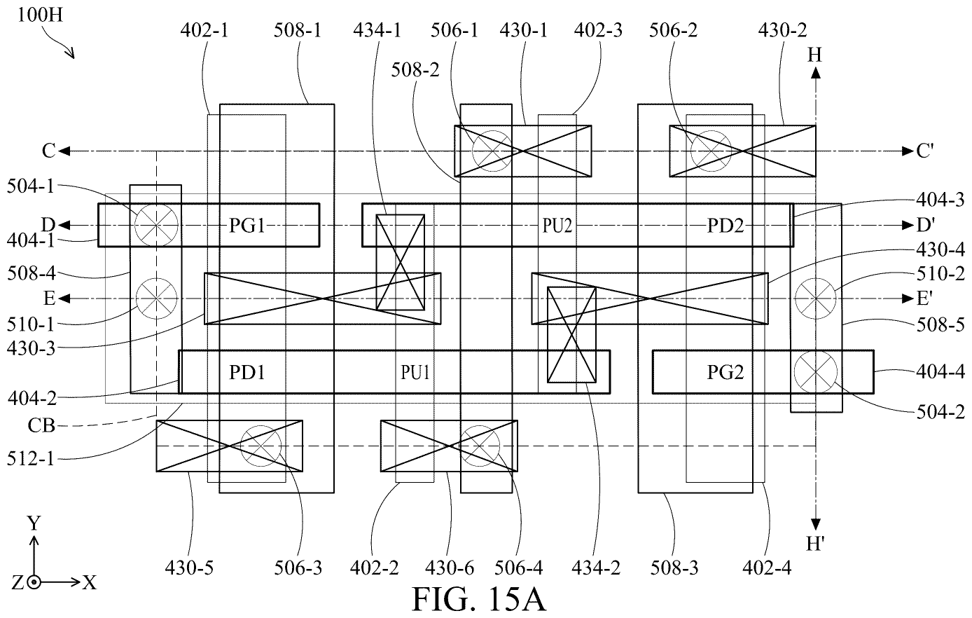

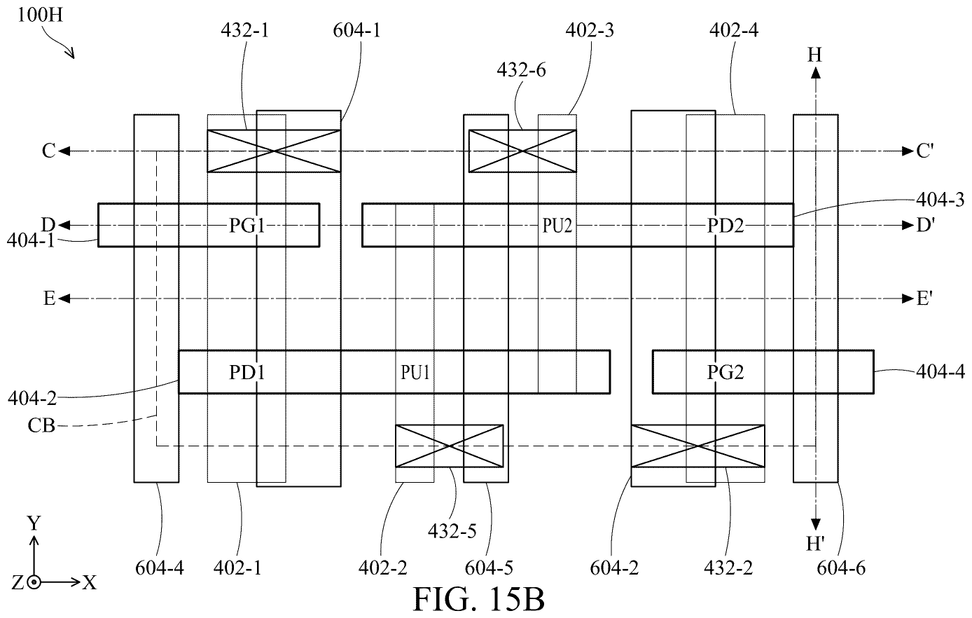

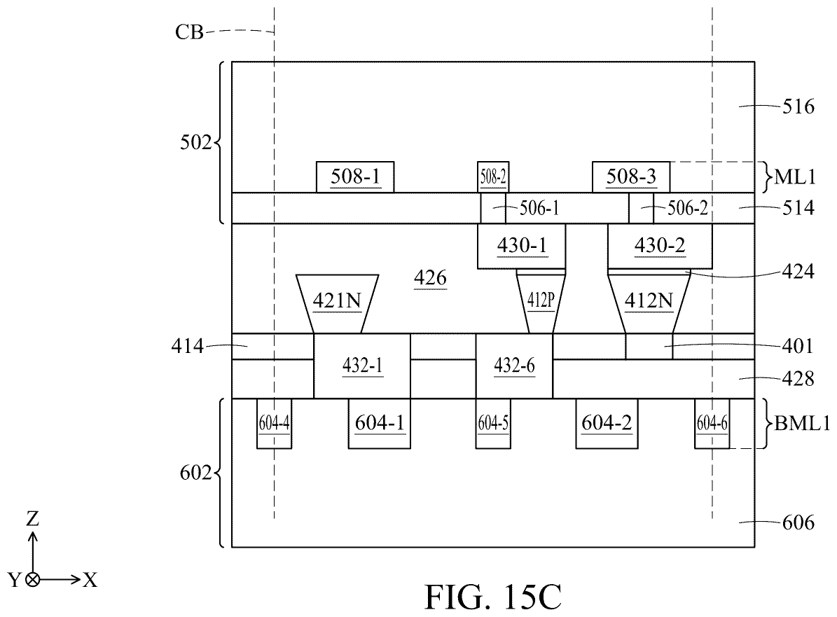

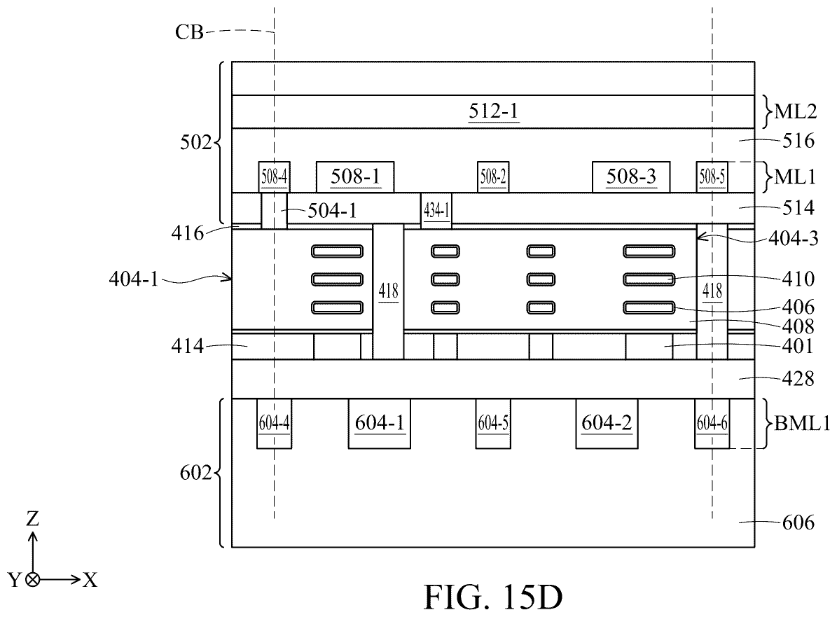

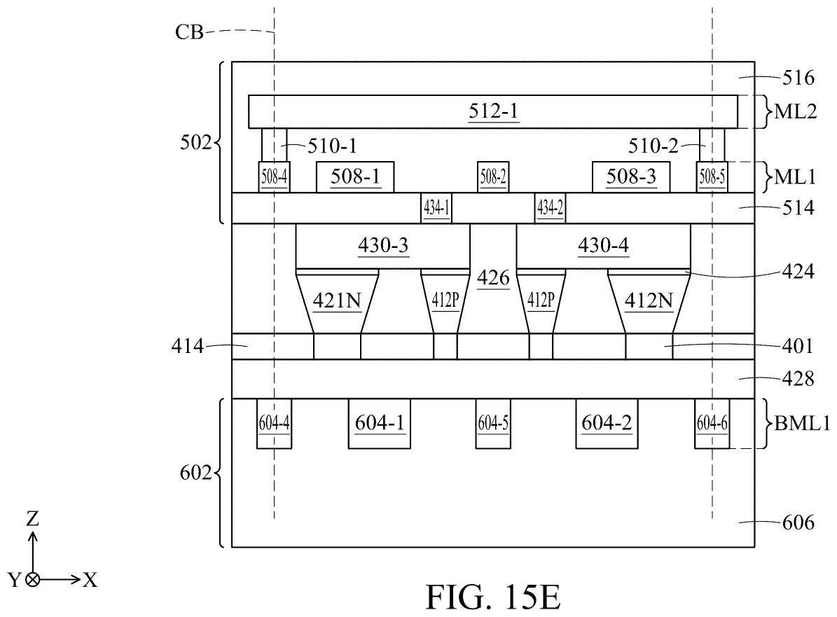

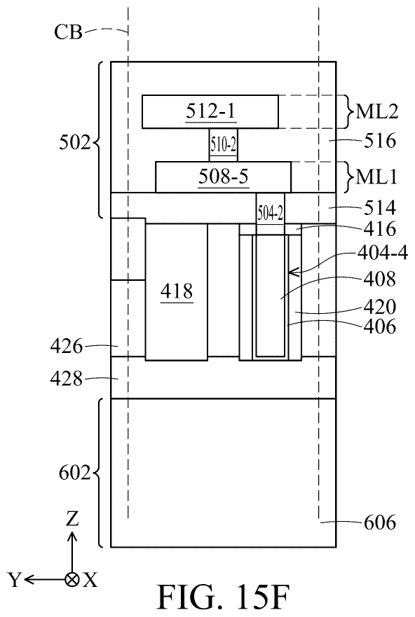

FIGS. 15A and 15B illustrate top views (or layouts) of an SRAM cell 100H in a semiconductor device, in accordance with some alternative embodiments of the present disclosure, in which FIG. 15A illustrates the features in a device region and a front-side interconnection structure, and FIG. 15B illustrates the features in the device region and a back-side interconnection structure.

FIG. 15C illustrates an X-Z cross-sectional view of the SRAM cell 100H in the semiconductor device along a line C-C′ in FIGS. 15A and 15B, in accordance with some alternative embodiments of the present disclosure. FIG. 15D illustrates an X-Z cross-sectional view of the SRAM cell 100H in the semiconductor device along a line D-D′ in FIGS. 15A and 15B, in accordance with some alternative embodiments of the present disclosure. FIG. 15E illustrates an X-Z cross-sectional view of the SRAM cell 100H in the semiconductor device along a line E-E′ in FIGS. 15A and 15B, in accordance with some alternative embodiments of the present disclosure. FIG. 15F illustrates a Y-Z cross-sectional view of the SRAM cell 100H in the semiconductor device along a line H-H′ in FIGS. 15A and 15B, in accordance with some alternative embodiments of the present disclosure.

The SRAM cell 101H is similar to the SRAM cell 101G discussed above, except that the metal conductor 604-5 discussed above is also used as VDD line rather than enhancing the isolation of the metal conductors 604-1 and 604-2. The SRAM cell 101H further includes source/drain contacts 432-5 and 432-6 similar to the source/drain contacts 432-3 and 432-4 shown in FIG. 11B. Therefore, the metal conductor 604-5 is electrically connected to the source/drain feature 412P of the pull-up transistor PU1 through the source/drain contact 432-5, and is electrically connected to the source/drain feature 412P of the pull-up transistor PU2 through the source/drain contact 432-6. In some embodiments, the metal conductor 604-5 may also be referred to as (back-side) VDD conductor or (back-side) VDD line.

The embodiments disclosed herein relate to semiconductor devices, and more particularly to semiconductor devices including the metal conductors for the bit-line and bit-line-bar that are under or at the back-side of the SRAM cells (more specifically, functional transistors). Furthermore, the present embodiments provide one or more of the following advantages. The metal conductors for bit-line and bit-line-bar at the back-side provides a reduced routing complexity for the SRAM cells, a lower circuit resistance, and a lower parasitic capacitance, which improves the performance of the SRAM cells, such as RC delay. Furthermore, the gate structures do not affect (back-side) source/drain contacts electrically connected to the metal conductors for bit-line and bit-line-bar, thereby improving the reliability of the read/write operations of the SRAM cells.

Thus, one of the embodiments of the present disclosure describes a semiconductor device that includes a transistor cell, an isolation feature, an inter-layer dielectric layer, a bit-line conductor extending in a first direction, a bit-line-bar conductor extending in the first direction, a first VSS conductor extending in the first direction, and a second VSS conductor extending in the first direction. The transistor cell has a first pass-gate transistor and a first pull-down transistor sharing a first active area, and a second pass-gate transistor and a first pull-down transistor sharing a second active area. The isolation feature is around the first active area and the second active area. The inter-layer dielectric layer is over the isolation feature. Each of the isolation feature and the inter-layer dielectric layer has a dielectric constant that is about 3 to about 5. The bit-line conductor is under and electrically connected to a source/drain feature of the first pass-gate transistor. The bit-line conductor is under and electrically connected to a source/drain feature of the second pass-gate transistor. The first VSS conductor is over and electrically connected to a source/drain feature of the first pull-down transistor. The second VSS conductor is over and electrically connected to a source/drain feature of the second pull-down transistor. A width of the first VSS conductor and the second VSS conductor in a second direction perpendicular to the first direction is greater than a width of the bit-line conductor and the bit-line-bar conductor in the second direction.

In some embodiments, a ratio of the width of the first VSS conductor and the second VSS conductor to the width of the bit-line conductor and the bit-line-bar conductor is in a range from about 1.05 to about 3.

In some embodiments, a thickness of the first VSS conductor and the second VSS conductor is less than a thickness of the bit-line conductor and the bit-line-bar conductor.

In some embodiments, a ratio of the thickness of the bit-line conductor and the bit-line-bar conductor to the thickness of the first VSS conductor and the second VSS conductor is in a range from about 1.5 to about 10.

In some embodiments, the semiconductor device further includes a first word-line conductor extending in the second direction. The first word-line conductor is over the first VSS conductor and the second VSS conductor and is electrically connected to gate structures of the first pass-gate transistor and the second pass-gate transistor.

In some embodiments, the semiconductor device further includes a second word-line conductor extending in the second direction. The second word-line conductor is over and electrically connected to the first word-line conductor.

In some embodiments, the semiconductor device further includes a third VSS conductor extending in the second direction and adjacent to the first word-line conductor. The third VSS conductor is over and electrically connected to the first VSS conductor and the second VSS conductor.

In some embodiments, the bit-line conductor and the bit-line-bar conductor are asymmetric shapes in a top view.

In some embodiments, the transistor cell further includes a first pull-up transistor and a second pull-up transistor. The semiconductor device further includes a VDD conductor over and electrically connected to source/drain features of the first pull-up transistor and the second pull-up transistor.

In some embodiments, the transistor cell further includes a first pull-up transistor and a second pull-up transistor. The semiconductor device further includes a VDD conductor under and electrically connected to source/drain features of the first pull-up transistor and the second pull-up transistor.

In some embodiments, the semiconductor device further includes a dummy metal conductor between the bit-line conductor and the bit-line-bar conductor in the second direction. The dummy metal conductor is electrically isolated from the transistor cell.

In another of the embodiments, discussed is a semiconductor device including a transistor cell. The transistor cell has a first pass-gate transistor, a second pass-gate transistor, a first pull-down transistor, and a second pull-down transistor over a substrate and in a device region. The semiconductor device further includes a first interconnection structure over the device region and a second interconnection structure under the device region. The first interconnection structure includes a first metal layer over the substrate and disposed in a first dielectric layer and a second metal layer over the first metal layer and disposed in the first dielectric layer. The first metal layer includes a first VSS conductor extending in a first direction and electrically connected to a source/drain feature of the first pull-down transistor and a second VSS conductor extending in the first direction and electrically connected to a source/drain feature of the second pull-down transistor. The second metal layer includes a first word-line conductor extending in a second direction perpendicular to the first direction and electrically connected to gate structures of the first pass-gate transistor and the second pass-gate transistor. The second interconnection structure includes a third metal layer under the substrate and disposed in a second dielectric layer. The third first metal layer includes a bit-line conductor extending in the first direction and electrically connected to a source/drain feature of the first pass-gate transistor and a bit-line-bar conductor extending in the first direction and electrically connected to a source/drain feature of the second pass-gate transistor. A first width of the first VSS conductor and the second VSS conductor in the second direction perpendicular to the first direction is greater than a second width of the bit-line conductor and the bit-line-bar conductor in the second direction. A first thickness of the first VSS conductor and the second VSS conductor is less than a second thickness of the bit-line conductor and the bit-line-bar conductor.

In some embodiments, a ratio of the first width to the second width is in a range from about 1.05 to about 3 and a ratio of the second thickness to the first thickness is in a range from about 1.5 to about 10.

In some embodiments, the semiconductor device further includes a fourth metal layer over the second metal layer. The fourth metal layer includes a second word-line conductor extending in the second direction and electrically connected to the first word-line conductor.

In some embodiments, the transistor cell further includes a first pull-up transistor and a second pull-up transistor. The first metal layer further includes a first VDD conductor extending in the first direction and electrically connected to source/drain features of the first pull-up transistor and the second pull-up transistor.

In some embodiments, the third metal layer further comprises dummy metal conductor extending in the first direction and on opposite sides of the bit-line conductor and the bit-line-bar conductor in the second direction.

In some embodiments, the third metal layer further comprises a second VDD conductor extending in the first direction and electrically connected to the source/drain features of the first pull-up transistor and the second pull-up transistor.

In yet another of the embodiments, discussed is a semiconductor device that includes a transistor cell, source/drain contacts, an inter-layer dielectric layer, a first VSS conductor, a second VSS conductor, and a VDD conductor extending in a first direction and in a first front-side metal layer over the substrate, and a bit-line conductor and a bit-line-bar conductor extending in the first direction and in a back-side metal layer under the substrate. The transistor cell has a first pass-gate transistor, a second pass-gate transistor, a first pull-down transistor, a second pull-down transistor, a first pull-up transistor, and a second pull-up transistor. Each of the first pass-gate transistor, the second pass-gate transistor, the first pull-down transistor, the second pull-down transistor, the first pull-up transistor, and the second pull-up transistor includes a channel layer and source/drain features attached to the channel layer. The source/drain contacts are over the source/drain features. The conductivity of the source/drain contacts is greater than that of the source/drain features. The inter-layer dielectric layer surrounds the source/drain contacts. The first VSS conductor is electrically connected to a source/drain feature of the first pull-down transistor, the second VSS conductor is electrically connected to a source/drain feature of the second pull-down transistor, and the VDD conductor is electrically connected to source/drain features of the first pull-up transistor and the second pull-up transistor. The bit-line conductor is electrically connected to a source/drain feature of the first pass-gate transistor and the bit-line-bar conductor is electrically connected to a source/drain feature of the second pass-gate transistor. The first VSS conductor and the second VSS conductor have wider widths in the second direction and thinner thicknesses than the bit-line conductor and the bit-line-bar conductor.

In some embodiments, the semiconductor device further includes a word-line conductor extending in the second direction and in a second front-side metal layer over the first front-side metal layer. The word-line conductor is electrically connected to gate structures of the first pass-gate transistor and the second pass-gate transistor.

In some embodiments, the bit-line conductor and the bit-line-bar conductor are bent shapes in a top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a transistor cell having a first pass-gate transistor and a first pull-down transistor sharing a first active area, and a second pass-gate transistor and a first pull-down transistor sharing a second active area;
an isolation feature around the first active area and the second active area;
an inter-layer dielectric layer over the isolation feature, wherein each of the isolation feature and the inter-layer dielectric layer has a dielectric constant that is about 3 to about 5;
a bit-line conductor extending in a first direction, wherein the bit-line conductor is under and electrically connected to a source/drain feature of the first pass-gate transistor;
a bit-line-bar conductor extending in the first direction, wherein the bit-line conductor is under and electrically connected to a source/drain feature of the second pass-gate transistor;
a first VSS conductor extending in the first direction, wherein the first VSS conductor is over and electrically connected to a source/drain feature of the first pull-down transistor; and
a second VSS conductor extending in the first direction, wherein the second VSS conductor is over and electrically connected to a source/drain feature of the second pull-down transistor,
wherein a width of the first VSS conductor and the second VSS conductor in a second direction perpendicular to the first direction is greater than a width of the bit-line conductor and the bit-line-bar conductor in the second direction.

2. The semiconductor device of claim 1, wherein a ratio of the width of the first VSS conductor and the second VSS conductor to the width of the bit-line conductor and the bit-line-bar conductor is in a range from about 1.05 to about 3.

3. The semiconductor device of claim 1, wherein a thickness of the first VSS conductor and the second VSS conductor is less than a thickness of the bit-line conductor and the bit-line-bar conductor.

4. The semiconductor device of claim 3, wherein a ratio of the thickness of the bit-line conductor and the bit-line-bar conductor to the thickness of the first VSS conductor and the second VSS conductor is in a range from about 1.5 to about 10.

5. The semiconductor device of claim 1, further comprising:
a first word-line conductor extending in the second direction, wherein the first word-line conductor is over the first VSS conductor and the second VSS conductor and is electrically connected to gate structures of the first pass-gate transistor and the second pass-gate transistor.

6. The semiconductor device of claim 5, further comprising:
a second word-line conductor extending in the second direction, wherein the second word-line conductor is over and electrically connected to the first word-line conductor.

7. The semiconductor device of claim 5, further comprising:
a third VSS conductor extending in the second direction and adjacent to the first word-line conductor, wherein the third VSS conductor is over and electrically connected to the first VSS conductor and the second VSS conductor.

8. The semiconductor device of claim 1, wherein the bit-line conductor and the bit-line-bar conductor are asymmetric shapes in a top view.

9. The semiconductor device of claim 1, wherein the transistor cell further comprises a first pull-up transistor and a second pull-up transistor,
wherein the semiconductor device further comprises a VDD conductor over and electrically connected to source/drain features of the first pull-up transistor and the second pull-up transistor.

10. The semiconductor device of claim 1, wherein the transistor cell further comprises a first pull-up transistor and a second pull-up transistor,
wherein the semiconductor device further comprises a VDD conductor under and electrically connected to source/drain features of the first pull-up transistor and the second pull-up transistor.

11. The semiconductor device of claim 1, further comprising:
a dummy metal conductor between the bit-line conductor and the bit-line-bar conductor in the second direction, wherein the dummy metal conductor is electrically isolated from the transistor cell.

12. A semiconductor device, comprising:
a transistor cell having a first pass-gate transistor, a second pass-gate transistor, a first pull-down transistor, and a second pull-down transistor over a substrate and in a device region;
a first interconnection structure over the device region, wherein the first interconnection structure comprises:
a first metal layer over the substrate and disposed in a first dielectric layer, wherein the first metal layer comprises a first VSS conductor extending in a first direction and electrically connected to a source/drain feature of the first pull-down transistor and a second VSS conductor extending in the first direction and electrically connected to a source/drain feature of the second pull-down transistor; and
a second metal layer over the first metal layer and disposed in the first dielectric layer, wherein the second metal layer comprises a first word-line conductor extending in a second direction perpendicular to the first direction and electrically connected to gate structures of the first pass-gate transistor and the second pass-gate transistor; and
a second interconnection structure under the device region, wherein the second interconnection structure comprises:
a third metal layer under the substrate and disposed in a second dielectric layer, wherein third first metal layer comprises a bit-line conductor extending in the first direction and electrically connected to a source/drain feature of the first pass-gate transistor and a bit-line-bar conductor extending in the first direction and electrically connected to a source/drain feature of the second pass-gate transistor,
wherein a first width of the first VSS conductor and the second VSS conductor in the second direction is greater than a second width of the bit-line conductor and the bit-line-bar conductor in the second direction,
wherein a first thickness of the first VSS conductor and the second VSS conductor is less than a second thickness of the bit-line conductor and the bit-line-bar conductor.

13. The semiconductor device of claim 12, wherein a ratio of the first width to the second width is in a range from about 1.05 to about 3 and a ratio of the second thickness to the first thickness is in a range from about 1.5 to about 10.

14. The semiconductor device of claim 12, further comprising:
a fourth metal layer over the second metal layer, wherein the fourth metal layer comprises a second word-line conductor extending in the second direction and electrically connected to the first word-line conductor.

15. The semiconductor device of claim 12, wherein the transistor cell further comprises a first pull-up transistor and a second pull-up transistor,
wherein the first metal layer further comprises a first VDD conductor extending in the first direction and electrically connected to source/drain features of the first pull-up transistor and the second pull-up transistor.

16. The semiconductor device of claim 15, wherein the third metal layer further comprises a dummy metal conductor extending in the first direction and on opposite sides of the bit-line conductor and the bit-line-bar conductor in the second direction.

17. The semiconductor device of claim 16, wherein the third metal layer further comprises a second VDD conductor extending in the first direction and electrically connected to the source/drain features of the first pull-up transistor and the second pull-up transistor.

18. A semiconductor device, comprising:
a transistor cell having a first pass-gate transistor, a second pass-gate transistor, a first pull-down transistor, a second pull-down transistor, a first pull-up transistor, and a second pull-up transistor over a substrate, wherein each of the first pass-gate transistor, the second pass-gate transistor, the first pull-down transistor, the second pull-down transistor, the first pull-up transistor, and the second pull-up transistor comprises:
a channel layer; and
source/drain features attached to the channel layer;
source/drain contacts over the source/drain features, wherein the conductivity of the source/drain contacts is greater than that of the source/drain features;
an inter-layer dielectric layer surrounds the source/drain contacts;
a first VSS conductor, a second VSS conductor, and a VDD conductor extending in a first direction and in a first front-side metal layer over the substrate, wherein the first VSS conductor is electrically connected to a source/drain feature of the first pull-down transistor, the second VSS conductor is electrically connected to a source/drain feature of the second pull-down transistor, and the VDD conductor is electrically connected to source/drain features of the first pull-up transistor and the second pull-up transistor; and
a bit-line conductor and a bit-line-bar conductor extending in the first direction and in a back-side metal layer under the substrate, wherein the bit-line conductor is electrically connected to a source/drain feature of the first pass-gate transistor and the bit-line-bar conductor is electrically connected to a source/drain feature of the second pass-gate transistor,
wherein the first VSS conductor and the second VSS conductor have wider widths in a second direction perpendicular to the first direction and thinner thicknesses than the bit-line conductor and the bit-line-bar conductor.

19. The semiconductor device of claim 18, further comprising:
a word-line conductor extending in the second direction and in a second front-side metal layer over the first front-side metal layer, wherein the word-line conductor is electrically connected to gate structures of the first pass-gate transistor and the second pass-gate transistor.

20. The semiconductor device of claim 18, wherein the bit-line conductor and the bit-line-bar conductor are bent shapes in a top view.
